(19) United States
(12) Patent Application Publication
(10) Pub. No.: US 2011/0290317 A1
(43) Pub. Date: Dec. 1, 2011

(54) ELECTRONIC DEVICE MODULE COMPRISING POLYOLEFIN COPOLYMER WITH LOW UNSATURATION AND OPTIONAL VINYL SILANE

(76) Inventors: John Naumovitz, Midland, MI (US); Rajen M. Patel, Lake Jackson, TX (US); Shaofu Wu, Sugar Land, MI (US); Debra H. Niemann, Lake Jackson, TX (US)

(21) Appl. No.: 13/116,520

(22) Filed: May 26, 2011

Related U.S. Application Data
(60) Provisional application No. 61/348,483, filed on May 26, 2010.

(51) Int. Cl. H01L 31/0216

(52) U.S. Cl. 136/256

(57) ABSTRACT

An electronic device module comprising:
A. At least one electronic device, e.g., a solar cell, and
B. A polymeric material in intimate contact with at least one surface of the electronic device, the polymeric material comprising (1) an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000, (2) optionally, a vinyl silane, (3) optionally, a free radical initiator, e.g., a peroxide or azo compound, or a photoinitiator, e.g., benzophenone, and (4) optionally, a co-agent.

### CROSS REFERENCE TO RELATED APPLICATION

This application claims priority from U.S. provisional application Ser. No. 61/348,483, filed May 26, 2010, which is incorporated herein by reference in its entirety. This application is also related to U.S. Provisional Application No. 61/222,371 filed Jul. 6, 2009; U.S. Ser. No. 60/826,328 filed Sep. 20, 2006; and U.S. Ser. No. 60/865,965 filed Nov. 15, 2006; the disclosures of which are incorporated herein by references for purposes of U.S. prosecution.

### FIELD OF THE INVENTION

This invention relates to electronic device modules. In one aspect, the invention relates to electronic device modules comprising an electronic device, e.g., a solar or photovoltaic (PV) cell, and a protective polymeric material while in another aspect, the invention relates to electronic device modules in which the protective polymeric material is an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000. In yet another aspect, the invention relates to a method of making an electronic device module.

### BACKGROUND OF THE INVENTION

Polymeric materials are commonly used in the manufacture of modules comprising one or more electronic devices including, but not limited to, solar cells (also known as photovoltaic cells), liquid crystal panels, electro-luminescent devices and plasma display units. The modules often comprise an electronic device in combination with one or more substrates, e.g., one or more glass cover sheets, often positioned between two substrates in which one or both of the substrates comprise glass, metal, plastic, rubber or another material. The polymeric materials are typically used as the encapsulant or sealant for the module or depending upon the design of the module, as a skin layer component of the module, e.g., a backskin in a solar cell module. Typical polymeric materials for these purposes include silicone resins, epoxy resins, polyvinyl butyral resins, cellulose acetate, ethylene-vinyl acetate copolymer (EVA) and ionomers.

United States Patent Application Publication 2001/0045229 A1 identifies a number of properties desirable in any polymeric material that is intended for use in the construction of an electronic device module. These properties include (i) protecting the device from exposure to the outside environment, e.g., moisture and air, particularly over long periods of time (ii) protecting against mechanical shock, (iii) strong adhesion to the electronic device and substrates, (iv) easy processing, including sealing, (v) good transparency, particularly in applications in which light or other electromagnetic radiation is important, e.g., solar cell modules, (vi) short cure times with protection of the electronic device from mechanical stress resulting from polymer shrinkage during cure, (vii) high electrical resistance with little, if any, electrical conductance, and (viii) low cost. No one polymeric material delivers maximum performance on all of these properties in any particular application, and usually trade-offs are made to maximize the performance of properties most important to a particular application, e.g., transparency and protection against the environment, at the expense of properties secondary in importance to the application, e.g., cure time and cost. Combinations of polymeric materials are also employed, either as a blend or as separate components of the module.

EVA copolymers with a high content (28 to 35 wt %) of units derived from the vinyl acetate monomer are commonly used to make encapsulant film for use in photovoltaic (PV) modules. See, for example, WO 95/22844, 99/04971, 99/05206 and 2004/055908. EVA resins are typically stabilized with ultra-violet (UV) light additives, and they are typically crosslinked during the solar cell lamination process using peroxides to improve heat and creep resistance to a temperature between about 80 and 90 C. However, EVA resins are less than ideal PV cell encapsulating film material for several reasons. For example, EVA film progressively darkens in intense sunlight due to the EVA resin chemically degrading under the influence of UV light. This discoloration can result in a greater than 30% loss in power output of the solar module after as little as four years of exposure to the environment. EVA resins also absorb moisture and are subject to decomposition.

Moreover and as noted above, EVA resins are typically stabilized with UV additives and crosslinked during the solar cell lamination and/or encapsulation process using peroxides to improve heat resistance and creep at high temperature, e.g., 80 to 90° C. However, because of the C═O bonds in the EVA molecular structure that absorbs UV radiation and the presence of residual peroxide crosslinking agent in the system after curing, an additive package is used to stabilize the EVA against UV-induced degradation. The residual peroxide is believed to be the primary oxidizing reagent responsible for the generation of chromophores (e.g., U.S. Pat. No. 6,093,757). Additives such as antioxidants, UV-stabilizers, UV-absorbers and others can stabilize the EVA, but at the same time the additive package can also block UV-wavelengths below 360 nanometers (nm).

Photovoltaic module efficiency depends on photovoltaic cell efficiency and the sun light wavelength passing through the encapsulant. One of the most fundamental limitations on the efficiency of a solar cell is the band gap of its semi-conducting material, i.e., the energy required to boost an electron from the bound valence band into the mobile conduction band. Photons with less energy than the band gap pass through the module without being absorbed. Photons with energy higher than the band gap are absorbed, but their excess energy is wasted (dissipated as heat). In order to increase the photovoltaic cell efficiency, “tandem” cells or multi-junction cells are used to broaden the wavelength range for energy conversion. In addition, in many of the thin film technologies such as amorphous silicon, cadmium telluride, or copper indium gallium selenide, the band gap of the semi-conductive materials is different than that of mono-crystalline silicon. These photovoltaic cells will convert light into electricity for wavelength below 360 nm. For these photovoltaic cells, an encapsulant that can absorb wavelengths below 360 nm is needed to maintain the PV module efficiency.

U.S. Pat. Nos. 6,320,116 and 6,586,271 teach another important property of these polymeric materials, particularly those materials used in the construction of solar cell modules. This property is thermal creep resistance, i.e., resistance to the permanent deformation of a polymer over a period of time as a result of temperature. Thermal creep resistance, generally, is directly proportional to the melting temperature of a polymer. Solar cell modules designed for use in architectural application often need to show excellent resistance to thermal creep at temperatures of 90° C. or higher. For materials with low melting temperatures, e.g., EVA, crosslinking the polymeric material is often necessary to give it higher thermal creep resistance.

Crosslinking, particularly chemical crosslinking, while addressing one problem, e.g., thermal creep, can create other problems. For example, EVA, a common polymeric material used in the construction of solar cell modules and which has a rather low melting point, is often crosslinked using an organic peroxide initiator. While this addresses the thermal creep problem, it creates a corrosion problem, i.e., total crosslinking is seldom, if ever, fully achieved and this leaves residual peroxide in the EVA. This remaining peroxide can promote oxidation and degradation of the EVA polymer and/or electronic device, e.g., through the release of acetic acid over the life of the electronic device module. Moreover, the addition of organic peroxide to EVA requires careful temperature control to avoid premature crosslinking.

Another potential problem with peroxide-initiated crosslinking is the buildup of crosslinked material on the metal surfaces of the process equipment. During extrusion runs, high residence time is experienced at all metal flow surfaces. Over longer periods of extrusion time, crosslinked material can form at the metal surfaces and require cleaning of the equipment. The current practice to minimize gel formation, i.e., this crosslinking of polymer on the metal surfaces of the processing equipment, is to use low processing temperatures which, in turn, reduces the production rate of the extruded product.

One other property that can be important in the selection of a polymeric material for use in the manufacture of an electronic device module is thermoplasticity, i.e., the ability to be softened, molded and formed. For example, if the polymeric material is to be used as a backskin layer in a frameless module, then it should exhibit thermoplasticity during lamination as described in U.S. Pat. No. 5,741,370. This thermoplasticity, however, must not be obtained at the expense of effective thermal creep resistance.

### SUMMARY OF THE INVENTION

In one embodiment, the invention is an electronic device module comprising:
A. At least one electronic device, and
B. A polymeric material in intimate contact with at least one surface of the electronic device, the polymeric material comprising (1) an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000, (2) optionally, a vinyl silane, e.g., vinyl tri-ethoxy silane or vinyl tri-methoxy silane, in an amount of at least about 0.1 wt % based on the weight of the copolymer, (3) free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based on the weight of the copolymer.

“In intimate contact” and like terms mean that the polymeric material is in contact with at least one surface of the device or other article in a similar manner as a coating is in contact with a substrate, e.g., little, if any gaps or spaces between the polymeric material and the face of the device and with the material exhibiting good to excellent adhesion to the face of the device. After extrusion or other method of applying the polymeric material to at least one surface of the electronic device, the material typically forms and/or cures to a film that can be either transparent or opaque and either flexible or rigid. If the electronic device is a solar cell or other device that requires unobstructed or minimally obstructed access to sunlight or to allow a user to read information from it, e.g., a plasma display unit, then that part of the material that covers the active or “business” surface of the device is highly transparent.

The module can further comprise one or more other components, such as one or more glass cover sheets, and in these embodiments, the polymeric material usually is located between the electronic device and the glass cover sheet in a sandwich configuration. If the polymeric material is applied as a film to the surface of the glass cover sheet opposite the electronic device, then the surface of the film that is in contact with that surface of the glass cover sheet can be smooth or uneven, e.g., embossed or textured.

Typically, the polymeric material is a ethylene-based polymer. The polymeric material can fully encapsulate the electronic device, or it can be in intimate contact with only a portion of it, e.g., laminated to one face surface of the device. Optionally, the polymeric material can further comprise a scorch inhibitor, and depending upon the application for which the module is intended, the chemical composition of the copolymer and other factors, the copolymer can remain uncrosslinked or be crosslinked. If crosslinked, then it is crosslinked such that it contains less than about 85 percent xylene soluble extractables as measured by ASTM 2765-95.

In another embodiment, the invention is the electronic device module as described in the two embodiments above except that the polymeric material in intimate contact with at least one surface of the electronic device is a co-extruded material in which at least one outer skin layer (i) does not contain peroxide for crosslinking, and (ii) is the surface which comes into intimate contact with the module. Typically, this outer skin layer exhibits good adhesion to glass. This outer skin of the co-extruded material can comprise any one of a number of different polymers, but is typically the same polymer as the polymer of the peroxide-containing layer but without the peroxide. This embodiment of the invention allows for the use of higher processing temperatures which, in turn, allows for faster production rates without unwanted gel formation in the encapsulating polymer due to extended contact with the metal surfaces of the processing equipment. In another embodiment, the extruded product comprises at least three layers in which the skin layer in contact with the electronic module is without peroxide, and the peroxide-containing layer is a core layer.

In another embodiment, the invention is a method of manufacturing an electronic device module, the method comprising the steps of:
A. Providing at least one electronic device, and
B. Contacting at least one surface of the electronic device with a polymeric material comprising (1) an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000, (2) optionally, a vinyl silane, (3) optionally, a free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based upon the weight of the copolymer.

In another embodiment the invention is a method of manufacturing an electronic device, the method comprising the steps of:
A. Providing at least one electronic device, and
B. Contacting at least one surface of the electronic device with a polymeric material comprising (1) an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000, (2) optionally, a vinyl silane, e.g., vinyl tri-ethoxy silane or vinyl tri-methoxy silane, in an amount of at least about 0.1 wt % based on the weight of the copolymer, (3) optionally a free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based on the weight of the copolymer.

In a variant on both of these two method embodiments, the module further comprises at least one translucent cover layer disposed apart from one face surface of the device, and the polymeric material is interposed in a sealing relationship between the electronic device and the cover layer. “In a sealing relationship” and like terms mean that the polymeric material adheres well to both the cover layer and the electronic device, typically to at least one face surface of each, and that it binds the two together with little, if any, gaps or spaces between the two module components (other than any gaps or spaces that may exist between the polymeric material and the cover layer as a result of the polymeric material applied to the cover layer in the form of an embossed or textured film, or the cover layer itself is embossed or textured).

Moreover, in both of these method embodiments, the polymeric material can further comprise a scorch inhibitor, and the method can optionally include a step in which the copolymer is crosslinked, e.g., either contacting the electronic device and/or glass cover sheet with the polymeric material under crosslinking conditions, or exposing the module to crosslinking conditions after the module is formed such that the polyolefin copolymer contains less than about 85 percent xylene soluble extractables as measured by ASTM 2765-95. Crosslinking conditions include heat (e.g., a temperature of at least about 160° C.), radiation (e.g., at least about 15 mega-rad if by E-beam, or 0.05 joules/cm² if by UV light), moisture (e.g., a relative humidity of at least about 50%), etc.

In another variant on these method embodiments, the electronic device is encapsulated, i.e., fully engulfed or enclosed, within the polymeric material. In another variant on these embodiments, the glass cover sheet is treated with a silane coupling agent, e.g., (-amino propyl tri-ethoxy silane. In yet another variant on these embodiments, the polymeric material further comprises a graft polymer to enhance its adhesive property relative to the one or both of the electronic device and glass cover sheet. Typically the graft polymer is made in situ simply by grafting the polyolefin copolymer with an unsaturated organic compound that contains a carbonyl group, e.g., maleic anhydride.

In another embodiment, the invention is an ethylene/non-polar α-olefin polymeric film characterized in that the film has (i) greater than or equal to (≧) 90% transmittance over the wavelength range from 400 to 1100 nanometers (nm), and (ii) a water vapor transmission rate (WVTR) of less than (<) about 50, preferably <about 15, grams per square meter per day (g/m²-day) at 38 C and 100% relative humidity (RH).

In one embodiment, the invention is an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C. Preferably, the ethylene-based polymer compositions comprise up to about 3 long chain branches/1000 carbons, more preferably from about 0.01 to about 3 long chain branches/1000 carbons. The ethylene-based polymer composition can have a ZSVR of at least 2. The ethylene-based polymer compositions can be further characterized by comprising less than 20 vinylidene unsaturation unit/1,000,000C. The ethylene-based polymer compositions can have a bimodal molecular weight distribution (MWD) or a multi-modal MWD. The ethylene-based polymer compositions can have a comonomer distribution profile comprising a mono or bimodal distribution from 35° C. to 120° C., excluding purge. The ethylene-based polymer compositions can comprise a single DSC melting peak. The ethylene-based polymer compositions can comprise a weight average molecular weight (Mw) from about 17,000 to about 220,000.

Fabricated articles comprising the novel polymer compositions are also contemplated, especially in the form of at least one film layer. Other embodiments include thermoplastic formulations comprising the novel polymer composition and at least one natural or synthetic polymer.

The ethylene-based polymer composition can be at least partially cross-linked (at least 5% (weight) gel).

### BRIEF DESCRIPTION OF THE DRAWINGS

FIG. 1 is a schematic of one embodiment of an electronic device module of this invention, i.e., a rigid photovoltaic (PV) module.

FIG. 2 is a schematic of another embodiment of an electronic device module of this invention, i.e., a flexible PV module.

FIG. 3 is a schematic drawing for obtaining peak temperature, half width and median temperature from CEF.

FIG. 4 is a graph of several examples and comparative examples of CEF.

### DESCRIPTION OF THE PREFERRED EMBODIMENTS

The polyolefin copolymers useful in the practice of this invention can have a density of equal to and greater than 0.9 gm/cm³, but can also have a density of less than about 0.9, preferably less than about 0.89, more preferably less than about 0.885, even more preferably less than about 0.88 and even more preferably less than about 0.875, g/cm³. The polyolefin copolymers typically have a density greater than about 0.85, and more preferably greater than about 0.86, g/cm³. Low density polyolefin copolymers are generally characterized as amorphous, flexible and having good optical properties, e.g., high transmission of visible and UV-light and low haze.

The polyolefin copolymers useful in the practice of this invention and that are made with a single site catalyst such as a metallocene catalyst or constrained geometry catalyst, typically have a melting point of less than about 95, preferably less than about 90, more preferably less than about 85, even more preferably less than about 80 and still more preferably less than about 75, ° C. For polyolefin copolymers made with multi-site catalysts, e.g., Ziegler-Natta and Phillips catalysts, the melting point is typically less than about 125, preferably less than about 120, more preferably less than about 115 and even more preferably less than about 110, ° C. The melting point is measured by differential scanning calorimetry (DSC) as described, for example, in U.S. Pat. No. 5,783,638. Polyolefin copolymers with a low melting point often exhibit desirable flexibility and thermoplasticity properties useful in the fabrication of the modules of this invention.

The polyolefin copolymers useful in the practice of this invention include ethylene/α-olefin interpolymers having a α-olefin content of between about 15, preferably at least about 20 and even more preferably at least about 25, wt % based on the weight of the interpolymer. These interpolymers typically have an α-olefin content of less than about 50, preferably less than about 45, more preferably less than about 40 and even more preferably less than about 35, wt % based on the weight of the interpolymer. The α-olefin content is measured by ¹³C nuclear magnetic resonance (NMR) spectroscopy using the procedure described in Randall (Rev. Macromol. Chem. Phys., C29 (2 &3)). Generally, the greater the α-olefin content of the interpolymer, the lower the density and the more amorphous the interpolymer, and this translates into desirable physical and chemical properties for the protective polymer component of the module.

The α-olefin is preferably a C₃₋₂₀ linear, branched or cyclic α-olefin. The term interpolymer refers to a polymer made from at least two monomers. It includes, for example, copolymers, terpolymers and tetrapolymers. Examples of C₃₋₂₀ α-olefins include propene, 1-butene, 4-methyl-1-pentene, 1-hexene, 1-octene, 1-decene, 1-dodecene, 1-tetradecene, 1-hexadecene, and 1-octadecene. The α-olefins can also contain a cyclic structure such as cyclohexane or cyclopentane, resulting in an α-olefin such as 3-cyclohexyl-1-propene (allyl cyclohexane) and vinyl cyclohexane. Although not α-olefins in the classical sense of the term, for purposes of this invention certain cyclic olefins, such as norbornene and related olefins, are α-olefins and can be used in place of some or all of the α-olefins described above. Similarly, styrene and its related olefins (for example, α-methylstyrene, etc.) are α-olefins for purposes of this invention. Acrylic and methacrylic acid and their respective ionomers, and acrylates and methacrylates, however, are not α-olefins for purposes of this invention. Illustrative polyolefin copolymers include ethylene/propylene, ethylene/butene, ethylene/1-hexene, ethylene/1-octene, ethylene/styrene, and the like. Ethylene/acrylic acid (EAA), ethylene/methacrylic acid (EMA), ethylene/acrylate or methacrylate, ethylene/vinyl acetate and the like are not polyolefin copolymers of this invention. Illustrative terpolymers include ethylene/propylene/1-octene, ethylene/propylene/butene, ethylene/butene/1-octene, and ethylene/butene/styrene. The copolymers can be random or blocky.

More specific examples of olefinic interpolymers useful as blend components in this invention include very low density polyethylene (VLDPE) (e.g., FLEXOMER® ethylene/1-hexene polyethylene made by The Dow Chemical Company), homogeneously branched, linear ethylene/α-olefin copolymers (e.g. TAFMER® by Mitsui Petrochemicals Company Limited and EXACT® by Exxon Chemical Company), and homogeneously branched, substantially linear ethylene/α-olefin polymers (e.g., AFFINITY® and ENGAGE® polyethylene available from The Dow Chemical Company). The more preferred polyolefin copolymers are the homogeneously branched linear and substantially linear ethylene copolymers. The substantially linear ethylene copolymers are especially preferred, and are more fully described in U.S. Pat. Nos. 5,272,236, 5,278,272 and 5,986,028.

The polyolefin copolymers useful as blend components in the practice of this invention also include propylene, butene and other alkene-based copolymers, e.g., copolymers comprising a majority of units derived from propylene and a minority of units derived from another α-olefin (including ethylene). Exemplary polypropylenes useful in the practice of this invention include the VERSIFY® polymers available from The Dow Chemical Company, and the VISTAMAXX® polymers available from ExxonMobil Chemical Company.

Blends of any of the above olefinic interpolymers can also be used in this invention, and the polyolefin copolymers can be blended or diluted with one or more other polymers to the extent that the polymers are (i) miscible with one another, (ii) the other polymers have little, if any, impact on the desirable properties of the polyolefin copolymer, e.g., optics and low modulus, and (iii) the polyolefin copolymers of this invention constitute at least about 70, preferably at least about 75 and more preferably at least about 80, weight percent of the blend. Although not favored, EVA copolymer can be one of the diluting polymers.

The polyolefin copolymers useful in the practice of this invention have a Tg of less than about −35, preferably less than about −40, more preferably less than about −45 and even more preferably less than about −50, ° C. as measured by differential scanning calorimetry (DSC) using the procedure of ASTM D-3418-03. Moreover, typically the polyolefin copolymers used in the practice of this invention also have a melt index of less than about 100, preferably less than about 75, more preferably less than about 50 and even more preferably less than about 35, g/10 minutes. The typical minimum MI is about 1, and more typically it is about 5.

The polyolefin copolymers useful in the practice of this invention preferably have an SCBDI (Short Chain Branch Distribution Index) or CDBI (Composition Distribution Branch Index) as defined as the weight percent of the polymer molecules having comonomer content within 50 percent of the median total molar comonomer content. The CDBI of a polymer is readily calculated from data obtained from techniques known in the art, such as, for example, temperature rising elution fractionation (abbreviated herein as “TREF”) as described, for example, in Wild et al, Journal of Polymer Science, Poly. Phys. Ed., Vol. 20, p. 441 (1982), or as described in U.S. Pat. Nos. 4,798,081 and 5,008,204. The SCBDI or CDBI for the polyolefin copolymers used in the practice of this present invention is typically greater than about 50, preferably greater than about 60, more preferably greater than about 70, even more preferably greater than about 80, and most preferably greater than about 90 percent.

The polymeric material used in the practice of this invention is an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a single DSC melting peak; the ethylene-based polymer compositions can comprise a weight average molecular weight (Mw) from about 17,000 to about 220,000.

Due to the low density and modulus of the polyolefin copolymers used in the practice of this invention, these copolymers are typically cured or crosslinked at the time of contact or after, usually shortly after, the module has been constructed. Crosslinking is important to the performance of the copolymer in its function to protect the electronic device from the environment. Specifically, crosslinking enhances the thermal creep resistance of the copolymer and durability of the module in terms of heat, impact and solvent resistance. Crosslinking can be effected by any one of a number of different methods, e.g., by the use of thermally activated initiators, e.g., peroxides and azo compounds; photoinitiators, e.g., benzophenone; radiation techniques including sunlight, UV light, E-beam and x-ray; vinyl silane, e.g., vinyl tri-ethoxy or vinyl tri-methoxy silane; and moisture cure.

The free radical initiators used in the practice of this invention include any thermally activated compound that is relatively unstable and easily breaks into at least two radicals. Representative of this class of compounds are the peroxides, particularly the organic peroxides, and the azo initiators. Of the free radical initiators used as crosslinking agents, the dialkyl peroxides and diperoxyketal initiators are preferred. These compounds are described in the Encyclopedia of Chemical Technology, 3rd edition, Vol. 17, pp 27-90. (1982).

In the group of dialkyl peroxides, the preferred initiators are: dicumyl peroxide, di-t-butyl peroxide, t-butyl cumyl peroxide, 2,5-dimethyl-2,5-di(t-butylperoxy)-hexane, 2,5-dimethyl-2,5-di(t-amylperoxy)-hexane, 2,5-dimethyl-2,5-di(t-butylperoxy)hexyne-3,2,5-dimethyl-2,5-di(t-amylperoxy)hexyne-3, α,α-di[(t-butylperoxy)-isopropyl]-benzene, di-t-amyl peroxide, 1,3,5-tri-[(t-butylperoxy)-isopropyl]benzene, 1,3-dimethyl-3-(t-butylperoxy)butanol, 1,3-dimethyl-3-(t-amylperoxy)butanol and mixtures of two or more of these initiators.

In the group of diperoxyketal initiators, the preferred initiators are: 1,1-di(t-butylperoxy)-3,3,5-trimethylcyclohexane, 1,1-di(t-butylperoxy)cyclohexane n-butyl, 4,4-di(t-amylperoxy)valerate, ethyl 3,3-di(t-butylperoxy)butyrate, 2,2-di(t-amylperoxy)propane, 3,6,6,9,9-pentamethyl-3-ethoxycarbonylmethyl-1,2,4,5-tetraoxacyclononane, n-butyl-4,4-bis(t-butylperoxy)-valerate, ethyl-3,3-di(t-amylperoxy)-butyrate and mixtures of two or more of these initiators.

Other peroxide initiators, e.g., 00-t-butyl-O-hydrogen-monoperoxysuccinate; 00-t-amyl-0-hydrogen-monoperoxysuccinate and/or azo initiators e.g., 2,2′-azobis-(2-acetoxypropane), may also be used to provide a crosslinked polymer matrix. Other suitable azo compounds include those described in U.S. Pat. Nos. 3,862,107 and 4,129,531. Mixtures of two or more free radical initiators may also be used together as the initiator within the scope of this invention. In addition, free radicals can form from shear energy, heat or radiation.

The amount of peroxide or azo initiator present in the crosslinkable compositions of this invention can vary widely, but the minimum amount is that sufficient to afford the desired range of crosslinking. The minimum amount of initiator is typically at least about 0.05, preferably at least about 0.1 and more preferably at least about 0.25, wt % based upon the weight of the polymer or polymers to be crosslinked. The maximum amount of initiator used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

Free radical crosslinking initiation via electromagnetic radiation, e.g., sunlight, ultraviolet (UV) light, infrared (IR) radiation, electron beam, beta-ray, gamma-ray, x-ray and neutron rays, may also be employed. Radiation is believed to affect crosslinking by generating polymer radicals, which may combine and crosslink. The Handbook of Polymer Foams and Technology, supra, at pp. 198-204, provides additional teachings. Elemental sulfur may be used as a crosslinking agent for diene containing polymers such as EPDM and polybutadiene. The amount of radiation used to cure the copolymer will vary with the chemical composition of the copolymer, the composition and amount of initiator, if any, the nature of the radiation, and the like, but a typical amount of UV light is at least about 0.05, more typically at about 0.1 and even more typically at least about 0.5, Joules/cm², and a typical amount of E-beam radiation is at least about 0.5, more typically at least about 1 and even more typically at least about 1.5, megarads.

If sunlight or UV light is used to effect cure or crosslinking, then typically and preferably one or more photoinitiators are employed. Such photoinitiators include organic carbonyl compounds such as such as benzophenone, benzanthrone, benzoin and alkyl ethers thereof, 2,2-diethoxyacetophenone, 2,2-dimethoxy, 2 phenylacetophenone, p-phenoxy dichloroacetophenone, 2-hydroxycyclohexylphenone, 2-hydroxyisopropylphenone, and 1-phenylpropanedione-2-(ethoxy carboxyl)oxime. These initiators are used in known manners and in known quantities, e.g., typically at least about 0.05, more typically at least about 0.1 and even more typically about 0.5, wt % based on the weight of the copolymer.

If moisture, i.e., water, is used to effect cure or crosslinking, then typically and preferably one or more hydrolysis/condensation catalysts are employed. Such catalysts include Lewis acids such as dibutyltin dilaurate, dioctyltin dilaurate, stannous octonoate, and hydrogen sulfonates such as sulfonic acid.

Free radical crosslinking coagents, i.e. promoters or co-initiators, include multifunctional vinyl monomers and polymers, triallyl cyanurate and trimethylolpropane trimethacrylate, divinyl benzene, acrylates and methacrylates of polyols, allyl alcohol derivatives, and low molecular weight polybutadiene. Sulfur crosslinking promoters include benzothiazyl disulfide, 2-mercaptobenzothiazole, copper dimethyldithiocarbamate, dipentamethylene thiuram tetrasulfide, tetrabutylthiuram disulfide, tetramethylthiuram disulfide and tetramethylthiuram monosulfide.

These coagents are used in known amounts and known ways. The minimum amount of coagent is typically at least about 0.05, preferably at least about 0.1 and more preferably at least about 0.5, wt % based upon the weight of the polymer or polymers to be crosslinked. The maximum amount of coagent used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

One difficulty in using thermally activated free radical initiators to promote crosslinking, i.e., curing, of thermoplastic materials is that they may initiate premature crosslinking, i.e., scorch, during compounding and/or processing prior to the actual phase in the overall process in which curing is desired. With conventional methods of compounding, such as milling, Banbury, or extrusion, scorch occurs when the time-temperature relationship results in a condition in which the free radical initiator undergoes thermal decomposition which, in turn, initiates a crosslinking reaction that can create gel particles in the mass of the compounded polymer. These gel particles can adversely impact the homogeneity of the final product. Moreover, excessive scorch can so reduce the plastic properties of the material that it cannot be efficiently processed with the likely possibility that the entire batch will be lost.

One method of minimizing scorch is the incorporation of scorch inhibitors into the compositions. For example, British patent 1,535,039 discloses the use of organic hydroperoxides as scorch inhibitors for peroxide-cured ethylene polymer compositions. U.S. Pat. No. 3,751,378 discloses the use of N-nitroso diphenylamine or N,N′-dinitroso-para-phenylamine as scorch retardants incorporated into a polyfunctional acrylate crosslinking monomer for providing long Mooney scorch times in various copolymer formulations. U.S. Pat. No. 3,202,648 discloses the use of nitrites such as isoamyl nitrite, tert-decyl nitrite and others as scorch inhibitors for polyethylene. U.S. Pat. No. 3,954,907 discloses the use of monomeric vinyl compounds as protection against scorch. U.S. Pat. No. 3,335,124 describes the use of aromatic amines, phenolic compounds, mercaptothiazole compounds, bis(N,N-disubstituted-thiocarbamoyl)sulfides, hydroquinones and dialkyldithiocarbamate compounds. U.S. Pat. No. 4,632,950 discloses the use of mixtures of two metal salts of disubstituted dithiocarbamic acid in which one metal salt is based on copper.

One commonly used scorch inhibitor for use in free radical, particularly peroxide, initiator-containing compositions is 4-hydroxy-2,2,6,6-tetramethylpiperidin-1-oxyl also known as nitroxyl 2, or NR 1, or 4-oxypiperidol, or tanol, or tempol, or tmpn, or probably most commonly, 4-hydroxy-TEMPO or even more simply, h-TEMPO. The addition of 4-hydroxy-TEMPO minimizes scorch by “quenching” free radical crosslinking of the crosslinkable polymer at melt processing temperatures.

The preferred amount of scorch inhibitor used in the compositions of this invention will vary with the amount and nature of the other components of the composition, particularly the free radical initiator, but typically the minimum amount of scorch inhibitor used in a system of polyolefin copolymer with 1.7 weight percent (wt %) peroxide is at least about 0.01, preferably at least about 0.05, more preferably at least about 0.1 and most preferably at least about 0.15, wt % based on the weight of the polymer. The maximum amount of scorch inhibitor can vary widely, and it is more a function of cost and efficiency than anything else. The typical maximum amount of scorch inhibitor used in a system of polyolefin copolymer with 1.7 wt % peroxide does not exceed about 2, preferably does not exceed about 1.5 and more preferably does not exceed about 1, wt % based on the weight of the copolymer.

Any silane that will effectively graft to and crosslink the polyolefin copolymer can be used in the practice of this invention. Suitable silanes include unsaturated silanes that comprise an ethylenically unsaturated hydrocarbyl group, such as a vinyl, allyl, isopropenyl, butenyl, cyclohexenyl or (-(meth)acryloxy allyl group, and a hydrolyzable group, such as, for example, a hydrocarbyloxy, hydrocarbonyloxy, or hydrocarbylamino group. Examples of hydrolyzable groups include methoxy, ethoxy, formyloxy, acetoxy, proprionyloxy, and alkyl or arylamino groups. Preferred silanes are the unsaturated alkoxy silanes which can be grafted onto the polymer. These silanes and their method of preparation are more fully described in U.S. Pat. No. 5,266,627. Vinyl trimethoxy silane, vinyl triethoxy silane, (-(meth)acryloxy propyl trimethoxy silane and mixtures of these silanes are the preferred silane crosslinkers for is use in this invention. If filler is present, then preferably the crosslinker includes vinyl triethoxy silane.

The amount of silane crosslinker used in the practice of this invention can vary widely depending upon the nature of the polyolefin copolymer, the silane, the processing conditions, the grafting efficiency, the ultimate application, and similar factors, but typically at least 0.5, preferably at least 0.7, parts per hundred resin wt % is used based on the weight of the copolymer. Considerations of convenience and economy are usually the two principal limitations on the maximum amount of silane crosslinker used in the practice of this invention, and typically the maximum amount of silane crosslinker does not exceed 5, preferably it does not exceed 2, wt % based on the weight of the copolymer.

The silane crosslinker is grafted to the polyolefin copolymer by any conventional method, typically in the presence of a free radical initiator e.g. peroxides and azo compounds, or by ionizing radiation, etc. Organic initiators are preferred, such as any of those described above, e.g., the peroxide and azo initiators. The amount of initiator can vary, but it is typically present in the amounts described above for the crosslinking of the polyolefin copolymer.

While any conventional method can be used to graft the silane crosslinker to the polyolefin copolymer, one preferred method is blending the two with the initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

In another embodiment of the invention, the polymeric material further comprises a graft polymer to enhance the adhesion to one or more glass cover sheets to the extent that these sheets are components of the electronic device module. While the graft polymer can be any graft polymer compatible with the polyolefin copolymer of the polymeric material and which does not significantly compromise the performance of the polyolefin copolymer as a component of the module, typically the graft polymer is a graft polyolefin polymer and more typically, a graft polyolefin copolymer that is of the same composition as the polyolefin copolymer of the polymeric material. This graft additive is typically made in situ simply by subjecting the polyolefin copolymer to grafting reagents and grafting conditions such that at least a portion of the polyolefin copolymer is grafted with the grafting material.

Any unsaturated organic compound containing at least one ethylenic unsaturation (e.g., at least one double bond), at least one carbonyl group (—C═O), and that will graft to a polymer, particularly a polyolefin polymer and more particularly to a polyolefin copolymer, can be used as the grafting material in this embodiment of the invention. Representative of compounds that contain at least one carbonyl group are the carboxylic acids, anhydrides, esters and their salts, both metallic and nonmetallic. Preferably, the organic compound contains ethylenic unsaturation conjugated with a carbonyl group. Representative compounds include maleic, fumaric, acrylic, methacrylic, itaconic, crotonic, α-methyl crotonic, and cinnamic acid and their anhydride, ester and salt derivatives, if any. Maleic anhydride is the preferred unsaturated organic compound containing at least one ethylenic unsaturation and at least one carbonyl group.

The unsaturated organic compound content of the graft polymer is at least about 0.01 wt %, and preferably at least about 0.05 wt %, based on the combined weight of the polymer and the organic compound. The maximum amount of unsaturated organic compound content can vary to convenience, but typically it does not exceed about 10 wt %, preferably it does not exceed about 5 wt %, and more preferably it does not exceed about 2 wt %.

The unsaturated organic compound can be grafted to the polymer by any known technique, such as those taught in U.S. Pat. Nos. 3,236,917 and 5,194,509. For example, in the '917 patent the polymer is introduced into a two-roll mixer and mixed at a temperature of 60 C. The unsaturated organic compound is then added along with a free radical initiator, such as, for example, benzoyl peroxide, and the components are mixed at 30° C. until the grafting is completed. In the '509 patent, the procedure is similar except that the reaction temperature is higher, e.g., 210 to 300° C., and a free radical initiator is not used or is used at a reduced concentration.

An alternative and preferred method of grafting is taught in U.S. Pat. No. 4,950,541 by using a twin-screw devolatilizing extruder as the mixing apparatus. The polymer and unsaturated organic compound are mixed and reacted within the extruder at temperatures at which the reactants are molten and in the presence of a free radical initiator. Preferably, the unsaturated organic compound is injected into a zone maintained under pressure within the extruder.

The polymeric materials of this invention can comprise other additives as well. For example, such other additives include UV-stabilizers and processing stabilizers such as trivalent phosphorus compounds. The UV-stabilizers are useful in lowering the wavelength of electromagnetic radiation that can be absorbed by a PV module (e.g., to less than 360 nm), and include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus compounds include phosphonites (PEPQ) and phosphites (Weston 399, TNPP, P-168 and Doverphos 9228). The amount of UV-stabilizer is typically from about 0.1 to 0.8%, and preferably from about 0.2 to 0.5%. The amount of processing stabilizer is typically from about 0.02 to 0.5%, and preferably from about 0.05 to 0.15%.

Still other additives include, but are not limited to, antioxidants (e.g., hindered phenolics (e.g., Irganox® 1010 made by Ciba Geigy Corp.), cling additives, e.g., PIB, anti-blocks, anti-slips, pigments, anti-stats, and fillers (clear if transparency is important to the application). In-process additives, e.g. calcium stearate, water, etc., may also be used. These and other potential additives are used in the manner and amount as is commonly known in the art.

The polymeric materials of this invention are used to construct electronic device modules in the same manner and using the same amounts as the encapsulant materials known in the art, e.g., such as those taught in U.S. Pat. No. 6,586,271, US Patent Application Publication US2001/0045229 A1, WO 99/05206 and WO 99/04971. These materials can be used as “skins” for the electronic device, i.e., applied to one or both face surfaces of the device, or as an encapsulant in which the device is totally enclosed within the material. Typically, the polymeric material is applied to the device by one or more lamination techniques in which a layer of film formed from the polymeric material is applied first to one face surface of the device, and then to the other face surface of the device. In an alternative embodiment, the polymeric material can be extruded in molten form onto the device and allowed to congeal on the device. The polymeric materials of this invention exhibit good adhesion for the face surfaces of the device.

In one embodiment, the electronic device module comprises (i) at least one electronic device, typically a plurality of such devices arrayed in a linear or planar pattern, (ii) at least one glass cover sheet, typically a glass cover sheet over both face surfaces of the device, and (iii) at least one polymeric material. The polymeric material is typically disposed between the glass cover sheet and the device, and the polymeric material exhibits good adhesion to both the device and the sheet. If the device requires access to specific forms of electromagnetic radiation, e.g., sunlight, infrared, ultra-violet, etc., then the polymeric material exhibits good, typically excellent, transparency for that radiation, e.g., transmission rates in excess of 90, preferably in excess of 95 and even more preferably in excess of 97, percent as measured by UV-vis spectroscopy (measuring absorbance in the wavelength range of about 250-1200 nanometers. An alternative measure of transparency is the internal haze method of ASTM D-1003-00. If transparency is not a requirement for operation of the electronic device, then the polymeric material can contain opaque filler and/or pigment.

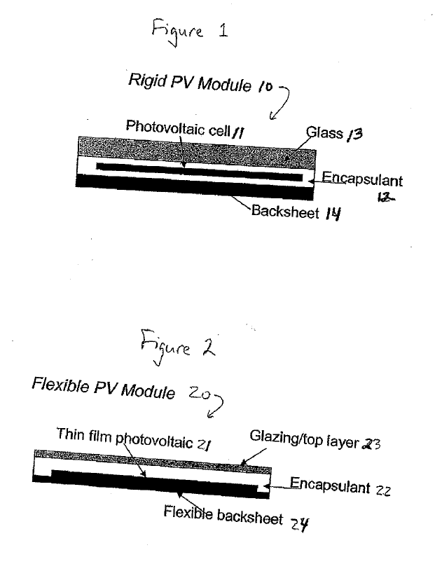

In FIG. 1, rigid PV module 10 comprises photovoltaic cell 11 surrounded or encapsulated by transparent protective layer or encapsulant 12 comprising a polyolefin copolymer used in the practice of this invention. Glass cover sheet 13 covers a front surface of the portion of the transparent protective layer disposed over PV cell 11. Backskin or back sheet 14, e.g., a second glass cover sheet or another substrate of any kind, supports a rear surface of the portion of transparent protective layer 12 disposed on a rear surface of PV cell 11. Backskin layer 14 need not be transparent if the surface of the PV cell to which it is opposed is not reactive to sunlight. In this embodiment, protective layer 12 encapsulates PV cell 11. The thicknesses of these layers, both in an absolute context and relative to one another, are not critical to this invention and as such, can vary widely depending upon the overall design and purpose of the module. Typical thicknesses for protective layer 12 are in the range of about 0.125 to about 2 millimeters (mm), and for the glass cover sheet and backskin layers in the range of about 0.125 to about 1.25 mm The thickness of the electronic device can also vary widely.

In FIG. 2, flexible PV module 20 comprises thin film photovoltaic 21 over-lain by transparent protective layer or encapsulant 22 comprising a polyolefin copolymer used in the practice of this invention. Glazing/top layer 23 covers a front surface of the portion of the transparent protective layer disposed over thin film PV 21. Flexible backskin or back sheet 24, e.g., a second protective layer or another flexible substrate of any kind, supports the bottom surface of thin film PV 21. Backskin layer 24 need not be transparent if the surface of the thin film cell which it is supporting is not reactive to sunlight. In this embodiment, protective layer 21 does not encapsulate thin film PV 21. The overall thickness of a typical rigid or flexible PV cell module will typically be in the range of about 5 to about 50 mm.

The modules described in FIGS. 1 and 2 can be constructed by any number of different methods, typically a film or sheet co-extrusion method such as blown-film, modified blown-film, calendaring and casting, and lamination. In one method and referring to FIG. 1, protective layer 14 is formed by first extruding a polyolefin copolymer over and onto the top surface of the PV cell and either simultaneously with or subsequent to the extrusion of this first extrusion, extruding the same, or different, polyolefin copolymer over and onto the back surface of the cell. Once the protective film is attached the PV cell, the glass cover sheet and backskin layer can be attached in any convenient manner, e.g., extrusion, lamination, etc., to the protective layer, with or without an adhesive. Either or both external surfaces, i.e., the surfaces opposite the surfaces in contact with the PV cell, of the protective layer can be embossed or otherwise treated to enhance adhesion to the glass and backskin layers. The module of FIG. 2 can be constructed in a similar manner, except that the backskin layer is attached to the PV cell directly, with or without an adhesive, either prior or subsequent to the attachment of the protective layer to the PV cell.

### Resin Production

All raw materials (ethylene, 1-octene) and the process solvent (a narrow boiling range high-purity isoparaffinic solvent trademarked Isopar E and commercially available from Exxon Mobil Corporation) are purified with molecular sieves before introduction into the reaction environment. Hydrogen is supplied in pressurized cylinders as a high purity grade and is not further purified. The reactor monomer feed (ethylene) stream is pressurized via mechanical compressor to above reaction pressure at 750 psig. The solvent and comonomer (1-octene) feed is pressurized via mechanical positive displacement pump to above reaction pressure at 750 psig. The individual catalyst components are manually batch diluted to specified component concentrations with purified solvent (Isopar E) and pressured to above reaction pressure at 750 psig. All reaction feed flows are measured with mass flow meters and independently controlled with computer automated valve control systems.

The continuous solution polymerization reactors consist of two liquid full, non-adiabatic, isothermal, circulating, and independently controlled loops operating in a series configuration. Each reactor has independent control of all fresh solvent, monomer, comonomer, hydrogen, and catalyst component feeds. The combined solvent, monomer, comonomer and hydrogen feed to each reactor is independently temperature controlled to anywhere between 5° C. to 50° C. and typically 40° C. by passing the feed stream through a heat exchanger. The fresh comonomer feed to the polymerization reactors can be manually aligned to add comonomer to one of three choices: the first reactor, the second reactor, or the common solvent and then split between both reactors proportionate to the solvent feed split. The total fresh feed to each polymerization reactor is injected into the reactor at two locations per reactor roughly with equal reactor volumes between each injection location. The fresh feed is controlled typically with each injector receiving half of the total fresh feed mass flow. The catalyst components are injected into the polymerization reactor through specially designed injection stingers and are each separately injected into the same relative location in the reactor with no contact time prior to the reactor. The primary catalyst component feed is computer controlled to maintain the reactor monomer concentration at a specified target. The two cocatalyst components are fed based on calculated specified molar ratios to the primary catalyst component. Immediately following each fresh injection location (either feed or catalyst), the feed streams are mixed with the circulating polymerization reactor contents with Kenics static mixing elements. The contents of each reactor are continuously circulated through heat exchangers responsible for removing much of the heat of reaction and with the temperature of the coolant side responsible for maintaining isothermal reaction environment at the specified temperature. Circulation around each reactor loop is provided by a screw pump. The effluent from the first polymerization reactor (containing solvent, monomer, comonomer, hydrogen, catalyst components, and molten polymer) exits the first reactor loop and passes through a control valve (responsible for maintaining the pressure of the first reactor at a specified target) and is injected into the second polymerization reactor of similar design. As the stream exits the reactor it is contacted with water to stop the reaction. In addition, various additives such as anti-oxidants, can be added at this point. The stream then goes through another set of Kenics static mixing elements to evenly disperse the catalyst kill and additives.

Following additive addition, the effluent (containing solvent, monomer, comonomer, hydrogen, catalyst components, and molten polymer) passes through a heat exchanger to raise the stream temperature in preparation for separation of the polymer from the other lower boiling reaction components. The stream then enters a two stage separation and devolatization system where the polymer is removed from the solvent, hydrogen, and unreacted monomer and comonomer. The recycled stream is purified before entering the reactor again. The separated and devolatized polymer melt is pumped through a die specially designed for underwater pelletization, cut into uniform solid pellets, dried, and transferred into a hopper. After validation of initial polymer properties the solid polymer pellets are manually dumped into a box for storage. Each box typically holds ˜1200 pounds of polymer pellets.

The non-polymer portions removed in the devolatilization step pass through various pieces of equipment which separate most of the ethylene which is removed from the system to a vent destruction unit (it is recycled in manufacturing units). Most of the solvent is recycled back to the reactor after passing through purification beds. This solvent can still have unreacted co-monomer in it that is fortified with fresh co-monomer prior to re-entry to the reactor. This fortification of the co-monomer is an essential part of the product density control method. This recycle solvent can still have some hydrogen which is then fortified with fresh hydrogen to achieve the polymer molecular weight target. A very small amount of solvent leaves the system as a co-product due to solvent carrier in the catalyst streams and a small amount of solvent that is part of commercial grade co-monomers.

| | | Ex. 3 | Ex. 1 | Ex. 2 |
|---|---|---|---|---|
| | Run # | 08C16R04 | 08C16R05 | 09C05R07V1 |
| Primary Reactor Feed Temperature | ° C. | 20 | 20 | 20 |
| Primary Reactor Total Solvent Flow | lbs/h | 1159 | 1161 | 1160 |
| Primary Reactor Total Ethylene Flow | lbs/h | 220 | 178 | 199 |
| Primary Reactor Total Comonomer Flow | lbs/h | 92 | 76 | 15 |
| Primary Reactor Feed Solvent/Ethylene Ratio | Ratio | 5.5 | 6.9 | 6.9 |
| Primary Reactor Fresh Hydrogen Flow | sccm | 6485 | 3383 | 701 |
| Secondary Reactor Feed Temperature | ° C. | 20 | 21 | 32 |
| Secondary Reactor Total Solvent Flow | lbs/h | 400 | 510 | 340 |
| Secondary Reactor Total Ethylene Flow | lbs/h | 153 | 196 | 127 |
| Secondary Reactor Total Comonomer Flow | lbs/h | 16.1 | 13.5 | 1.8 |
| Secondary Reactor Feed Solvent/Ethylene Ratio | Ratio | 2.7 | 2.7 | 2.8 |
| Secondary Reactor Fresh Hydrogen Flow | sccm | 2047 | 4990 | 21857 |
| Primary Reactor Control Temperature | ° C. | 155 | 140 | 180 |
| Primary Reactor Pressure | psig | 725 | 725 | 725 |
| Primary Reactor Ethylene Conversion | % | 81 | 92 | 91 |
| Primary Reactor Percent Solids | % | 16 | 16 | 13 |
| E-214B Heat Transfer Coefficient | BTU/hr | 7.6 | 6.7 | 9.1 |
| | ft³ ° F. | | | |
| Primary Reactor Polymer Residence Time | hrs | 0.25 | 0.27 | 0.29 |
| Secondary Reactor Control Temperature | ° C. | 190 | 190 | 190 |
| Secondary Reactor Pressure | psig | 729 | 731 | 730 |
| Secondary Reactor Ethylene Conversion | % | 87 | 87 | 85 |
| Secondary Reactor Percent Solids | % | 22 | 21 | 17 |
| E-216B Heat Transfer Coefficient | BTU/hr | 80 | 51 | 44 |
| | ft³ ° F. | | | |
| Secondary Reactor Polymer Residence Time | hrs | 0.10 | 0.10 | 0.12 |
| Primary Reactor Split | % | 53 | 50 | 56 |
| Primary Reactor Production Rate | lbs/h | 226 | 212 | 160 |
| Secondary Reactor Production Rate | lbs/h | 201 | 215 | 127 |
| Total production rate from MB | lbs/h | 427 | 426 | 287 |
| Primary Reactor Catalyst Efficiency | MM Lb | 10.9 | 8.6 | 2.3 |
| Secondary Reactor Catalyst Efficiency | MM Lb | 1.4 | 1.6 | 1.1 |
| 3. CATALYST | | | | |
| Primary Reactor Catalyst Type | — | DOC-6114 | DOC-6114 | DOC-6114 |
| Primary Reactor Catalyst Flow | lbs/h | 1.52 | 1.81 | 1.96 |
| Primary Reactor Catalyst Concentration | ppm | 13.67 | 13.67 | 34.96 |
| Primary Reactor Catalyst Efficiency | MM Lb | 10.87 | 8.56 | 2.31 |
| Primary Reactor Catalyst-1 Type | — | DOC-6114 | DOC-6114 | DOC-6114 |
| Primary Reactor Catalyst-1 Flow | lbs/h | 1.52 | 1.81 | 1.96 |
| Primary Reactor Catalyst-1 Concentration | ppm | 13.67 | 13.67 | 34.96 |
| Primary Reactor Catalyst-1 Mole Weight | mw | 90.86 | 90.86 | 90.86 |
| Primary Reactor Co-Catalyst-1 Molar Ratio | Ratio | 1.77 | 1.48 | 1.42 |
| Primary Reactor Co-Catalyst-1 Type | — | MMAO | MMAO | MMAO |
| Primary Reactor Co-Catalyst-1 Flow | lbs/h | 0.81 | 0.81 | 1.19 |
| Primary Reactor Co-Catalyst-1 Concentration | ppm | 596 | 596 | 1094 |
| Primary Reactor Co-Catalyst-2 Molar Ratio | Ratio | 7.11 | 6.91 | 6.97 |
| Primary Reactor Co-Catalyst-2 Type | — | RIBS-2 | RIBS-2 | RIBS-2 |
| Primary Reactor Co-Catalyst-2 Flow | lbs/h | 044 | 0.52 | 0.72 |
| Primary Reactor Co-Catalyst-2 Concentration | ppm | 99.6 | 99.6 | 199 |
| Secondary Reactor Catalyst Type | See Note | DOC-6114 | DOC-6114 | DOC-6114 |
| Secondary Reactor Catalyst Flow | lbs/h | 3.52 | 2.30 | 1.54 |
| Secondary Reactor Catalyst Concentration | ppm | 40 | 60 | 76 |
| Secondary Reactor Catalyst Efficiency | MM Lb | 1.43 | 1.56 | 1.08 |
| Secondary Reactor Co-Catalyst-1 Molar Ratio | Ratio | 1.48 | 1.50 | 1.21 |
| Secondary Reactor Co-Catalyst-1 Type | See Note | MMAO | MMAO | MMAO |
| Secondary Reactor Co-Catalyst-1 Flow | lbs/h | 4.62 | 4.59 | 1.68 |
| Secondary Reactor Co-Catalyst-1 Concentration | ppm | 596 | 596 | 1094 |
| Secondary Reactor Co-Catalyst-2 Molar Ratio | Ratio | 6.99 | 7.02 | 6.96 |
| Secondary Reactor Co-Catalyst-2 Type | See Note | RIBS-2 | RIBS-2 | RIBS-2 |
| Secondary Reactor Co-Catalyst-2 Flow | lbs/h | 2.93 | 2.88 | 1.22 |
| Secondary Reactor Co-Catalyst-2 Concentration | ppm | 100 | 100 | 199 |

CAS name for RIBS-2: Amines, bis(hydrogenated tallow alkyl)methyl, tetrakis(pentafluorophenyl)borate(1-)
CAS name for DOC-6114: Zirconium, [2,2″′-[1,3-propanediylbis(oxy-O)]bis[3″,5,5″-tris(1,1-dimethylethyl)-5′-methyl[1,1′:3′,1″-terphenyl]-2′-olato-O]]dimethyl-,(OC-6-33)-
MMAO = modified methyl aluminoxane

### Test Methods

### Density

Samples that are measured for density are prepared according to ASTM D 1928. Measurements are made within one hour of sample pressing using ASTM D792, Method B.

### Melt Index

Melt index, or I₂, is measured in accordance with ASTM D 1238, Condition 190° C./2.16 kg, and is reported in grams eluted per 10 minutes. I₁₀ is measured in accordance with ASTM D 1238, Condition 190° C./10 kg, and is reported in grams eluted per 10 minutes.

### DSC Crystallinity

Differential Scanning calorimetry (DSC) can be used to measure the melting and crystallization behavior of a polymer over a wide range of temperature. For example, the TA Instruments Q1000 DSC, equipped with an RCS (refrigerated cooling system) and an autosampler is used to perform this analysis. During testing, a nitrogen purge gas flow of 50 ml/min is used. Each sample is melt pressed into a thin film at about 175° C.; the melted sample is then air-cooled to room temperature (−25° C.). A 3-10 mg, 6 mm diameter specimen is extracted from the cooled polymer, weighed, placed in a light aluminum pan (ca 50 mg), and crimped shut. Analysis is then performed to determine its thermal properties.

The thermal behavior of the sample is determined by ramping the sample temperature up and down to create a heat flow versus temperature profile. First, the sample is rapidly heated to 180° C. and held isothermal for 3 minutes in order to remove its thermal history. Next, the sample is cooled to −40° C. at a 10° C./minute cooling rate and held isothermal at −40° C. for 3 minutes. The sample is then heated to 150° C. (this is the “second heat” ramp) at a 10° C./minute heating rate. The cooling and second heating curves are recorded. The cool curve is analyzed by setting baseline endpoints from the beginning of crystallization to −20° C. The heat curve is analyzed by setting baseline endpoints from −20° C. to the end of melt. The values determined are peak melting temperature (Tₘ), peak crystallization temperature (T_{c}), heat of fusion (H_{f}) (in Joules per gram), and the calculated % crystallinity for polyethylene samples using Equation 1:

% Crystallinity=((H_{f})/(292 J/g))×100 (Eq. 1).

The heat of fusion (H_{f}) and the peak melting temperature are reported from the second heat curve. Peak crystallization temperature is determined from the cooling curve.

### Dynamic Mechanical Spectroscopy (DMS) Frequency Sweep

Melt rheology, constant temperature frequency sweeps, were performed using a TA Instruments ARES rheometer equipped with 25 mm parallel plates under a nitrogen purge. Frequency sweeps were performed at 190° C. for all samples at a gap of 2.0 mm and at a constant strain of 10%. The frequency interval was from 0.1 to 100 radians/second. The stress response was analyzed in terms of amplitude and phase, from which the storage modulus (G′), loss modulus (G″), and dynamic melt viscosity (η*) were calculated.

### Gel Permeation Chromatography (GPC)

The GPC system consists of a Waters (Milford, Mass.) 150 C high temperature chromatograph (other suitable high temperatures GPC instruments include Polymer Laboratories (Shropshire, UK) Model 210 and Model 220) equipped with an on-board differential refractometer (RI). Additional detectors can include an IR4 infra-red detector from Polymer ChAR (Valencia, Spain), Precision Detectors (Amherst, Mass.) 2-angle laser light scattering detector Model 2040, and a Viscotek (Houston, Tex.) 150R 4-capillary solution viscometer. A GPC with the last two independent detectors and at least one of the first detectors is sometimes referred to as “3D-GPC”, while the term “GPC” alone generally refers to conventional GPC. Depending on the sample, either the 15-degree angle or the 90-degree angle of the light scattering detector is used for calculation purposes. Data collection is performed using Viscotek TriSEC software, Version 3, and a 4-channel Viscotek Data Manager DM400. The system is also equipped with an on-line solvent degassing device from Polymer Laboratories (Shropshire, UK). Suitable high temperature GPC columns can be used such as four 30 cm long Shodex HT803 13 micron columns or four 30 cm Polymer Labs columns of 20-micron mixed-pore-size packing (MixA LS, Polymer Labs). The sample carousel compartment is operated at 140° C. and the column compartment is operated at 150° C. The samples are prepared at a concentration of 0.1 grams of polymer in 50 milliliters of solvent. The chromatographic solvent and the sample preparation solvent contain 200 ppm of butylated hydroxytoluene (BHT). Both solvents are sparged with nitrogen. The polyethylene samples are gently stirred at 160° C. for four hours. The injection volume is 200 microliters. The flow rate through the GPC is set at 1 ml/minute.

The GPC column set is calibrated before running the Examples by running twenty-one narrow molecular weight distribution polystyrene standards. The molecular weight (MW) of the standards ranges from 580 to 8,400,000 grams per mole, and the standards are contained in 6 “cocktail” mixtures. Each standard mixture has at least a decade of separation between individual molecular weights. The standard mixtures are purchased from Polymer Laboratories (Shropshire, UK). The polystyrene standards are prepared at 0.025 g in 50 mL of solvent for molecular weights equal to or greater than 1,000,000 grams per mole and 0.05 g in 50 ml of solvent for molecular weights less than 1,000,000 grams per mole. The polystyrene standards were dissolved at 80° C. with gentle agitation for 30 minutes. The narrow standards mixtures are run first and in order of decreasing highest molecular weight component to minimize degradation. The polystyrene standard peak molecular weights are converted to polyethylene M_{w} using the Mark-Houwink K and a (sometimes referred to as a) values mentioned later for polystyrene and polyethylene. See the Examples section for a demonstration of this procedure.

With 3D-GPC absolute weight average molecular weight (“M_{w, Abs}”) and intrinsic viscosity are also obtained independently from suitable narrow polyethylene standards using the same conditions mentioned previously. These narrow linear polyethylene standards may be obtained from Polymer Laboratories (Shropshire, UK; Part No.'s PL2650-0101 and PL2650-0102).

The systematic approach for the determination of multi-detector offsets is performed in a manner consistent with that published by Balke, Mourey, et al. (Mourey and Balke, Chromatography Polym., Chapter 12, (1992)) (Balke, Thitiratsakul, Lew, Cheung, Mourey, Chromatography Polym., Chapter 13, (1992)), optimizing triple detector log (M_{w} and intrinsic viscosity) results from Dow 1683 broad polystyrene (American Polymer Standards Corp.; Mentor, Ohio) or its equivalent to the narrow standard column calibration results from the narrow polystyrene standards calibration curve. The molecular weight data, accounting for detector volume off-set determination, are obtained in a manner consistent with that published by Zimm (Zimm, B. H., J. Chem. Phys., 16, 1099 (1948)) and Kratochvil (Kratochvil, P., Classical Light Scattering from Polymer Solutions, Elsevier, Oxford, N.Y. (1987)). The overall injected concentration used in the determination of the molecular weight is obtained from the mass detector area and the mass detector constant derived from a suitable linear polyethylene homopolymer, or one of the polyethylene standards. The calculated molecular weights are obtained using a light scattering constant derived from one or more of the polyethylene standards mentioned and a refractive index concentration coefficient, dn/dc, of 0.104. Generally, the mass detector response and the light scattering constant should be determined from a linear standard with a molecular weight in excess of about 50,000 daltons. The viscometer calibration can be accomplished using the methods described by the manufacturer or alternatively by using the published values of suitable linear standards such as Standard Reference Materials (SRM) 1475a, 1482a, 1483, or 1484a. The chromatographic concentrations are assumed low enough to eliminate addressing 2^{nd} viral coefficient effects (concentration effects on molecular weight).

g′ by 3D-GPC

The index (g′) for the sample polymer is determined by first calibrating the light scattering, viscosity, and concentration detectors described in the Gel Permeation Chromatography method supra with SRM 1475a homopolymer polyethylene (or an equivalent reference). The light scattering and viscometer detector offsets are determined relative to the concentration detector as described in the calibration. Baselines are subtracted from the light scattering, viscometer, and concentration chromatograms and integration windows are then set making certain to integrate all of the low molecular weight retention volume range in the light scattering and viscometer chromatograms that indicate the presence of detectable polymer from the refractive index chromatogram. A linear homopolymer polyethylene is used to establish a Mark-Houwink (MH) linear reference line by injecting a broad molecular weight polyethylene reference such as SRM1475a standard, calculating the data file, and recording the intrinsic viscosity (IV) and molecular weight (M_{W}), each derived from the light scattering and viscosity detectors respectively and the concentration as determined from the RI detector mass constant for each chromatographic slice. For the analysis of samples the procedure for each chromatographic slice is repeated to obtain a sample Mark-Houwink line. Note that for some samples the lower molecular weights, the intrinsic viscosity and the molecular weight data may need to be extrapolated such that the measured molecular weight and intrinsic viscosity asymptotically approach a linear homopolymer GPC calibration curve. To this end, many highly-branched ethylene-based polymer samples require that the linear reference line be shifted slightly to account for the contribution of short chain branching before proceeding with the long chain branching index (g′) calculation.

A g-prime (gᵢ′) is calculated for each branched sample chromatographic slice (i) and measuring molecular weight (Mᵢ) according to Equation 2:

gᵢ′=(IV_{sample,i}/IV_{linear reference,j}) (Eq. 2),

where the calculation utilizes the IV_{linear referenced} at equivalent molecular weight, Mⱼ, in the linear reference sample. In other words, the sample IV slice (i) and reference IV slice (j) have the same molecular weight (Mᵢ=Mⱼ). For simplicity, the IV_{linear referenced,j} slices are calculated from a fifth-order polynomial fit of the reference Mark-Houwink Plot. The IV ratio, or gᵢ′, is only obtained at molecular weights greater than 3,500 because of signal-to-noise limitations in the light scattering data. The number of branches along the sample polymer (Bₙ) at each data slice (i) can be determined by using Equation 3, assuming a viscosity shielding epsilon factor of 0.75:

$${[ \frac{{IV}_{Sample , i}}{{IV}_{linear \_ reference , j}} ]}_{{M}_{i = j}}^{1.33} = {[ {( 1 + \frac{{B}_{n , i}}{7} )}^{1 / 2} + \frac{4}{9} \frac{{B}_{n , i}}{π} ]}^{- 1 / 2} . \qquad ( Eq . 3 )$$

Finally, the average LCBf quantity per 1000 carbons in the polymer across all of the slices (i) can be determined using Equation 4:

$$LCBf = \frac{{\sum }_{M = 3500}^{i} ( \frac{{B}_{n , i}}{{M}_{i} / 14000} {c}_{i} )}{\sum {c}_{i}} . \qquad ( Eq . 4 )$$

gpcBR Branching Index by 3D-GPC

In the 3D-GPC configuration the polyethylene and polystyrene standards can be used to measure the Mark-Houwink constants, K and α, independently for each of the two polymer types, polystyrene and polyethylene. These can be used to refine the Williams and Ward polyethylene equivalent molecular weights in application of the following methods.

The gpcBR branching index is determined by first calibrating the light scattering, viscosity, and concentration detectors as described previously. Baselines are then subtracted from the light scattering, viscometer, and concentration chromatograms. Integration windows are then set to ensure integration of all of the low molecular weight retention volume range in the light scattering and viscometer chromatograms that indicate the presence of detectable polymer from the refractive index chromatogram. Linear polyethylene standards are then used to establish polyethylene and polystyrene Mark-Houwink constants as described previously. Upon obtaining the constants, the two values are used to construct two linear reference conventional calibrations (“cc”) for polyethylene molecular weight and polyethylene intrinsic viscosity as a function of elution volume, as shown in Equations 5 and 6:

$$\begin{matrix}{M}_{PE} = {( \frac{{K}_{PS}}{{K}_{PE}} )}^{1 / {α}_{PE} + 1} \cdot {M}_{PS}^{{α}_{PS} + 1 / {α}_{PE} + 1} , \\ and & ( Eq . 5 ) \\ {[ η ]}_{PE} = {K}_{PS} \cdot {M}_{PS}^{α + 1} / {M}_{PE} . & ( Eq . 6 )\end{matrix}$$

The gpcBR branching index is a robust method for the characterization of long chain branching. See Yau, Wallace W., “Examples of Using 3D-GPC—TREF for Polyolefin Characterization”, Macromol. Symp., 2007, 257, 29-45. The index avoids the slice-by-slice 3D-GPC calculations traditionally used in the determination of g′ values and branching frequency calculations in favor of whole polymer detector areas and area dot products. From 3D-GPC data, one can obtain the sample bulk M_{w} by the light scattering (LS) detector using the peak area method. The method avoids the slice-by-slice ratio of light scattering detector signal over the concentration detector signal as required in the g′ determination.

$$\begin{matrix}{M}_{W} = {\sum }_{i} {w}_{i} {M}_{i} \\ = {\sum }_{i} ( \frac{{C}_{i}}{{\sum }_{i} {C}_{i}} ) {M}_{i} \\ = \frac{{\sum }_{i} {C}_{i} {M}_{i}}{{\sum }_{i} {C}_{i}} \\ = \frac{{\sum }_{i} {LS}_{i}}{{\sum }_{i} {C}_{i}} \\ = \frac{LS Area}{Conc . Area}\end{matrix} \qquad ( Eq . 7 )$$

The area calculation in Equation 7 offers more precision because as an overall sample area it is much less sensitive to variation caused by detector noise and GPC settings on baseline and integration limits. More importantly, the peak area calculation is not affected by the detector volume offsets. Similarly, the high-precision sample intrinsic viscosity (IV) is obtained by the area method shown in Equation 8:

$$\begin{matrix}IV = [ η ] \\ = {\sum }_{i} {w}_{i} {IV}_{i} \\ = {\sum }_{i} ( \frac{{C}_{i}}{{\sum }_{i} {C}_{i}} ) {IV}_{i} \\ = \frac{{\sum }_{i} {C}_{i} {IV}_{i}}{{\sum }_{i} {C}_{i}} \\ = \frac{{\sum }_{i} {DP}_{i}}{{\sum }_{i} {C}_{i}} \\ = \frac{DP Area}{Conc . Area} ,\end{matrix} \qquad ( Eq . 8 )$$

where DPᵢ stands for the differential pressure signal monitored directly from the online viscometer.

To determine the gpcBR branching index, the light scattering elution area for the sample polymer is used to determine the molecular weight of the sample. The viscosity detector elution area for the sample polymer is used to determine the intrinsic viscosity (IV or [η]) of the sample.

Initially, the molecular weight and intrinsic viscosity for a linear polyethylene standard sample, such as SRM1475a or an equivalent, are determined using the conventional calibrations for both molecular weight and intrinsic viscosity as a function of elution volume, per Equations 9 and 10:

$$\begin{matrix}{Mw}_{CC} = {\sum }_{i} ( \frac{{C}_{i}}{{\sum }_{i} {C}_{i}} ) {M}_{i} = {\sum }_{i} {w}_{i} {M}_{i} , \\ and & ( Eq . 9 ) \\ {[ η ]}_{CC} = {\sum }_{i} ( \frac{{C}_{i}}{{\sum }_{i} {C}_{i}} ) {IV}_{i} = {\sum }_{i} {w}_{i} {IV}_{i} . & ( Eq . 10 )\end{matrix}$$

Equation 11 is used to determine the gpcBR branching index:

$$gpcBR = [ ( \frac{{[ η ]}_{CC}}{[ η ]} ) \cdot {( \frac{{M}_{W}}{{M}_{W , CC}} )}^{{α}_{PE}} - 1 ] , \qquad ( Eq . 11 )$$

where [η] is the measured intrinsic viscosity, [η]_{cc} is the intrinsic viscosity from the conventional calibration, M_{w}, is the measured weight average molecular weight, and M_{w,cc} is the weight average molecular weight of the conventional calibration. The Mw by light scattering (LS) using Equation (7) is commonly referred to as the absolute Mw; while the Mw,cc from Equation (9) using the conventional GPC molecular weight calibration curve is often referred to as polymer chain Mw. All statistical values with the “cc” subscript are determined using their respective elution volumes, the corresponding conventional calibration as previously described, and the concentration (Cᵢ) derived from the mass detector response. The non-subscripted values are measured values based on the mass detector, LALLS, and viscometer areas. The value of K_{PE} is adjusted iteratively until the linear reference sample has a gpcBR measured value of zero. For example, the final values for and Log K for the determination of gpcBR in this particular case are 0.725 and −3.355, respectively, for polyethylene, and 0.722 and −3.993 for polystyrene, respectively.

Once the K and α values have been determined, the procedure is repeated using the branched samples. The branched samples are analyzed using the final Mark-Houwink constants as the best “cc” calibration values and applying Equations 10-14.

The interpretation of gpcBR is straight forward. For linear polymers, gpcBR calculated from Equation 14 will be close to zero since the values measured by LS and viscometry will be close to the conventional calibration standard. For branched polymers, gpcBR will be higher than zero, especially with high levels of LCB, because the measured polymer M_{w}, will be higher than the calculated M_{w,cc}, and the calculated IV_{cc} will be higher than the measured polymer IV. In fact, the gpcBR value represents the fractional IV change due the molecular size contraction effect as the result of polymer branching. A gpcBR value of 0.5 or 2.0 would mean a molecular size contraction effect of IV at the level of 50% and 200%, respectively, versus a linear polymer molecule of equivalent weight.

For these particular Examples, the advantage of using gpcBR in comparison to the g′ index and branching frequency calculations is due to the higher precision of gpcBR. All of the parameters used in the gpcBR index determination are obtained with good precision and are not detrimentally affected by the low 3D-GPC detector response at high molecular weight from the concentration detector. Errors in detector volume alignment also do not affect the precision of the gpcBR index determination. In other particular cases, other methods for determining M_{w} moments may be preferable to the aforementioned technique.

Unless otherwise stated, implicit from the context or conventional in the art, all parts and percentages are based on weight.

All applications, publications, patents, test procedures, and other documents cited, including priority documents, are fully incorporated by reference to the extent such disclosure is not inconsistent with the disclosed compositions and methods and for all jurisdictions in which such incorporation is permitted.

### A. CEF Method

Comonomer distribution analysis is performed with Crystallization Elution Fractionation (CEF) (PolymerChar in Spain) (B Monrabal et al, Macromol. Symp. 257, 71-79 (2007)). Ortho-dichlorobenzene (ODCB) with 600 ppm antioxidant butylated hydroxytoluene (BHT) is used as solvent. Sample preparation is done with autosampler at 160° C. for 2 hours under shaking at 4 mg/ml (unless otherwise specified). The injection volume is 300 μl. The temperature profile of CEF is: crystallization at 3° C./min from 110° C. to 30° C., the thermal equilibrium at 30° C. for 5 minutes, elution at 3° C./min from 30° C. to 140° C. The flow rate during crystallization is at 0.052 ml/min. The flow rate during elution is at 0.50 ml/min. The data is collected at one data point/second.

CEF column is packed by the Dow Chemical Company with glass beads at 125 um±6% (MO-SCI Specialty Products) with ⅛ inch stainless tubing. Glass beads are acid washed by MO-SCI Specialty with the request from the Dow Chemical Company. Column volume is 2 06 ml. Column temperature calibration is performed by using a mixture of NIST Standard Reference Material Linear polyethylene 1475a (1.0 mg/ml) and Eicosane (2 mg/ml) in ODCB. Temperature is calibrated by adjusting elution heating rate so that NIST linear polyethylene 1475a has a peak temperature at 101.0° C., and Eicosane has a peak temperature of 30.0° C. The CEF column resolution is calculated with a mixture of NIST linear polyethylene 1475a (1.0 mg/ml) and hexacontane (Fluka, purum, ≧97.0%, 1 mg/ml). A baseline separation of hexacontane and NIST polyethylene 1475a is achieved. The area of hexacontane (from 35.0 to 67.0° C.) to the area of NIST 1475a from 67.0 to 110.0° C. is 50 to 50, the amount of soluble fraction below 35.0° C. is <1.8 wt %.

The CEF column resolution is defined as:

$$Resolution = \frac{\begin{matrix}Peak temperature of NIST 1475 a - \\ Peak Temperature of Hexacontane\end{matrix}}{\begin{matrix}Half \text{-} height Width of NIST 1475 a + \\ Half \text{-} height Width of Hexacontane\end{matrix}}$$

The column resolution is 6.0

### CDC Method

Comonomer distribution constant (CDC) is calculated from comonomer distribution profile by CEF. CDC is defined as Comonomer Distribution Index divided by Comonomer Distribution Shape Factor multiplying by 100 (Equation 12)

$$\begin{matrix}CD C = \frac{Comonomer Distribution Index}{Comonomer Distribution Shape Factor} \\ = \frac{Comonomer Distribution Index}{Half Width \text{/} Stdev} * 100\end{matrix} \qquad Equation 12$$

Comonomer distribution index stands for the total weight fraction of polymer chains with the comonomer content ranging from 0.5 of median comonomer content (Cmedian) and 1.5 of Cmedian from 35.0 to 119.0° C. Comonomer Distribution Shape Factor is defined as a ratio of the half width of comonomer distribution profile divided by the standard deviation of comonomer distribution profile from the peak temperature (Tp).

CDC is calculated according to the following steps:

Obtain weight fraction at each temperature (T) (w_{T}(T)) from 35.0° C. to 119.0° C. with a temperature step of 0.200° C. from CEF according Equation 13.

$${\int }_{35}^{119.0} {w}_{T} ( T ) d T = 1 \qquad Equation 13$$

Calculate the mean temperature (Tₘₑₐₙ) at cumulative weight fraction of 0.500 (Equation 14)

$${\int }_{35}^{{T}_{mean}} {w}_{T} ( T ) d T = 0.5 \qquad Equation 14$$

Calculate the corresponding median comonomer content in mole % (C_{median}) at the median temperature (T_{median}) by using comonomer content calibration curve (Equation 15).

$$ln ( 1 - comonomercontent ) = - \frac{207.26}{273.12 + T} + 0.5533 \\ {R}^{2} = 0.997 \qquad Equation 15$$

(3i). Comonomer content calibration curve is constructed by using a series of reference materials with known amount of comonomer content. Eleven reference materials with narrow comonomer distribution (mono modal comonomer distribution in CEF from 35.0 to 119.0° C.) with weight average Mw of 35,000 to 115,000 (by conventional GPC) at a comonomer content ranging from 0.0 mole % to 7.0 mole % are analyzed with CEF at the same experimental conditions specified in CEF experimental sections.

(3ii). Comonomer content calibration is calculated by using the peak temperature (Tₚ) of each reference material and its comonomer content. The calibration is: R² is the correlation constant.

Comonomer Distribution Index is the total weight fraction with a comonomer content ranging from 0.5*C_{median} to 1.5*C_{median}. If T_{median} is higher than 98.0° C., Comonomer Distribution Index is defined as 0.95.

Maximum peak height is obtained from CEF comonomer distribution profile by searching each data point for the highest peak from 35.0° C. to 119.0° C. (if the two peaks are identical then the lower temperature peak is selected) Half width is defined as the temperature difference between the front temperature and the rear temperature at the half of the maximum peak height. The front temperature at the half of the maximum peak is searched forward from 35.0° C., while the rear temperature at the half of the maximum peak is searched backward from 119.0° C. In the case of a well defined bimodal distribution where the difference in the peak temperatures being equal to or larger than 1.1 times of the sum of half width of each peak, the half-width of the polymer is calculated as the arithmetic average of the half width of each peak.

The standard deviation of temperature (Stdev) is calculated according Equation 16:

$$Stdev = \sqrt{{\sum }_{35.0}^{119.0} {( T - {T}_{p} )}^{2} * {w}_{T} ( T )} \qquad Equation 16$$

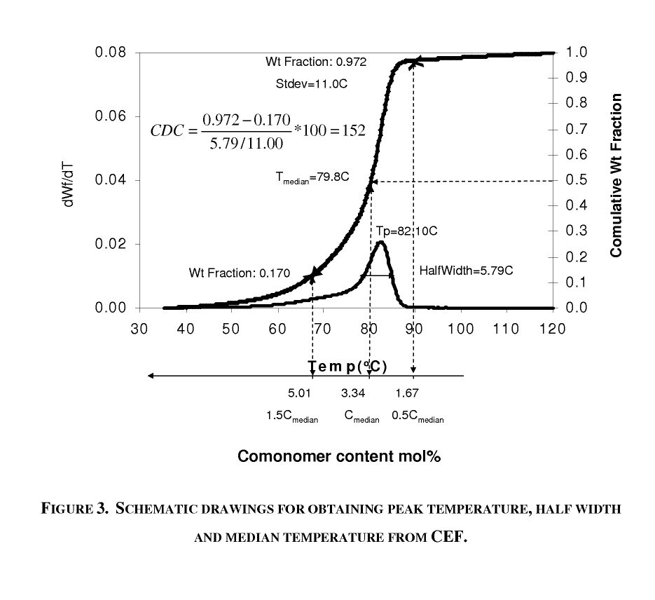

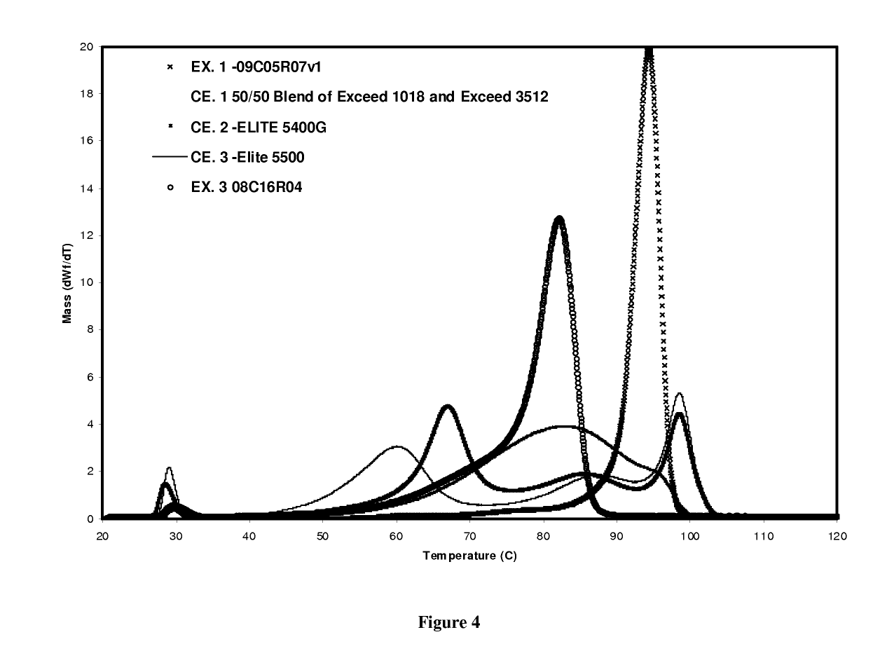

An example (Ex. 3 08C16R04) of comonomer distribution profile is shown in FIG. 3.

### B. Creep Zero Shear Viscosity Measurement Method:

Zero-shear viscosities are obtained via creep tests that were conducted on an AR-G2 stress controlled rheometer (TA Instruments; New Castle, Del.) using 25-mm-diameter parallel plates at 190° C. The rheometer oven is set to test temperature for at least 30 minutes prior to zeroing fixtures. At the testing temperature a compression molded sample disk is inserted between the plates and allowed to come to equilibrium for 5 minutes. The upper plate is then lowered down to 50 μm above the desired testing gap (1.5 mm) Any superfluous material is trimmed off and the upper plate is lowered to the desired gap. Measurements are done under nitrogen purging at a flow rate of 5 L/min Default creep time is set for 2 hours.

A constant low shear stress of 20 Pa is applied for all of the samples to ensure that the steady state shear rate is low enough to be in the Newtonian region. The resulting steady state shear rates are in the range of 10⁻³ to 10⁻⁴ s⁻¹ for the samples in this study. Steady state is determined by taking a linear regression for all the data in the last 10% time window of the plot of log (J(t)) vs. log(t), where J(t) is creep compliance and t is creep time. If the slope of the linear regression is greater than 0.97, steady state is considered to be reached, then the creep test is stopped. In all cases in this study the slope meets the criterion within 2 hours. The steady state shear rate is determined from the slope of the linear regression of all of the data points in the last 10% time window of the plot of ε vs. t, where ε is strain. The zero-shear viscosity is determined from the ratio of the applied stress to the steady state shear rate.

In order to determine if the sample is degraded during the creep test, a small amplitude oscillatory shear test is conducted before and after the creep test on the same specimen from 0.1 to 100 rad/s. The complex viscosity values of the two tests are compared. If the difference of the viscosity values at 0.1 rad/s is greater than 5%, the sample is considered to have degraded during the creep test, and the result is discarded.

### C. ZSVR Definition:

Zero-shear viscosity ratio (ZSVR) is defined as the ratio of the zero-shear viscosity (ZSV) of the branched polyethylene material to the ZSV of the linear polyethylene material at the equivalent weight average molecular weight (Mw-gpc) as shown in the equation below.

$$ZSVR = \frac{{η}_{0 B}}{{η}_{0 L}} = \frac{{η}_{0 B}}{2.29 * {10}^{- 15} {M}_{w - gpc}^{3.65}}$$

The ZSV value is obtained from creep test at 190° C. via the method described above. The Mw-gpc value is determined by the conventional GPC method as described above. The correlation between ZSV of linear polyethylene and its Mw-gpc was established based on a series of linear polyethylene reference materials. A description for the ZSV-Mw relationship can be found in the ANTEC proceeding: Karjala, Teresa P.; Sammler, Robert L.; Mangnus, Marc A.; Hazlitt, Lonnie G.; Johnson, Mark S.; Hagen, Charles M., Jr.; Huang, Joe W. L.; Reichek, Kenneth N. Detection of low levels of long-chain branching in polyolefins. Annual Technical Conference—Society of Plastics Engineers (2008), 66th 887-891.

### 1H NMR Method

3.26 g of stock solution is added to 0.133 g of polyolefin sample in 10 mm NMR tube. The stock solution is a mixture of tetrachloroethane-d2 (TCE) and perchloroethylene (50:50, w:w) with 0.001M Cr3+. The solution in the tube is purged with N2 for 5 minutes to reduce the amount of oxygen. The capped sample tube is left at room temperature overnight to swell the polymer sample. The sample is dissolved at 110° C. with shaking. The samples are free of the additives that may contribute to unsaturation, e.g. slip agents such as erucamide.

The 1H NMR are run with a 10 mm cryoprobe at 120° C. on Bruker AVANCE 400 MHz spectrometer.

Two experiments are run to get the unsaturation: the control and the double presaturation experiments.

For the control experiment, the data is processed with exponential window function with LB=1 Hz, baseline was corrected from 7 to −2 ppm. The signal from residual 1H of TCE is set to 100, the integral Itotal from −0.5 to 3 ppm is used as the signal from whole polymer in the control experiment. The number of CH₂ group, NCH₂, in the polymer is calculated as following:

NCH₂=Itotal/2

For the double presaturation experiment, the data is processed with exponential window function with LB=1 Hz, baseline was corrected from 6.6 to 4.5 ppm. The signal from residual 1H of TCE is set to 100, the corresponding integrals for unsaturations (Ivinylene, Itrisubstituted, Ivinyl and Ivinylidene) were integrated based on the region shown in the following Figure. The number of unsaturation unit for vinylene, trisubstituted, vinyl and vinylidene are calculated:

Nvinylene=Nvinylene/2

Ntrisubstituted=Itrisubstitute

Nvinyl=Ivinyl/2

Nvinylidene=Ivinylidene/2

The unsaturation unit/1,000,000 carbons is calculated as following:

Nvinylene/1,000,000C=(Nvinylene/NCH₂)*1,000,000

Ntrisubstituted/1,000,000C=(Ntrisubstituted/NCH₂)*1,000,000

Nvinyl/1,000,000C=(Nvinyl/NCH₂)*1,000,000

Nvinylidene/1,000,000C=(Nvinylidene/NCH₂)*1,000,000

The requirement for unsaturation NMR analysis includes: level of quantitation is 0.47±0.02/1,000,000 carbons for Vd2 with 200 scans (less than 1 hour data acquisition including time to run the control experiment) with 3.9 wt % of sample (for Vd2 structure, see Macromolecules, vol. 38, 6988, 2005), 10 mm high temperature cryoprobe. The level of quantitation is defined as signal to noise ratio of 10.

The chemical shift reference is set at 6.0 ppm for the 1H signal from residual proton from TCT-d2. The control is run with ZG pulse, TD 32768, NS 4, DS 12, SWH 10,000 Hz, AQ 1.64 s, D1 14 s. The double presaturation experiment is run with a modified pulse sequence, O1P 1.354 ppm, 02P 0.960 ppm, PL9 57 db, PL21 70 db, TD 32768, NS 200, DS 4, SWH 10,000 Hz, AQ 1.64 s, D1 1 s, D13 13 s.

### Gel Content

Gel content is determined in accordance to ASTM D2765-01 Method A in xylene. The sample is cut to required size using a razor blade.

### Film Testing Conditions

The following physical properties are measured on the films produced:
Total (Overall), Surface and Internal Haze: Samples measured for internal haze and overall haze are sampled and prepared according to ASTM D 1003. Internal haze was obtained via refractive index matching using mineral oil on both sides of the films. A Hazegard Plus (BYK-Gardner USA; Columbia, Md.) is used for testing. Surface haze is determined as the difference between overall haze and internal haze as shown in Equation 17. Surface haze tends to be related to the surface roughness of the film, where surface increases with increasing surface roughness. The surface haze to internal haze ratio is the surface haze value divided by the internal haze value as shown in Equation 18.

Haze=Internal Haze+Surface Haze (Eq. 17)

S/I=Surface Haze/Internal Haze (Eq. 18)
45° Gloss: ASTM D-2457.
MD and CD Elmendorf Tear Strength: ASTM D-1922
MD and CD Tensile Strength: ASTM D-882
Dart Impact Strength: ASTM D-1709
Puncture Strength: Puncture is measured on a Instron Model 4201 with Sintech Testworks Software Version 3.10. The specimen size is 6″×6″ and 4 measurements are made to determine an average puncture value. The film is conditioned for 40 hours after film production and at least 24 hours in an ASTM controlled laboratory. A 100 lb load cell is used with a round specimen holder 12.56″ square. The puncture probe is ½″ diameter polished stainless steel ball with a 7.5″ maximum travel length. There is no gauge length; the probe is as close as possible to, but not touching, the specimen. The crosshead speed used is 10″/minute. The thickness is measured in the middle of the specimen. The thickness of the film, the distance the crosshead traveled, and the peak load are used to determine the puncture by the software. The puncture probe is cleaned using a “Kim-wipe” after each specimen.
Unless otherwise indicated, all parts and percentages are by weight.

SPECIFIC EMBODIMENTS

| | | Density | I10 | I2 | |
|---|---|---|---|---|---|
| | | (g/cc) | (g/10 min) | (g/10 min) | I10/I2 |
| EX 1 | 08C16R05 | 0.912 | 11.5 | 1.5 | 7.7 |
| EX 2 | 09C05R07v1 | 0.937 | 7.1 | 0.4 | 16.1 |
| CE 1 | 50/50 Blend | 0.916 | 9.1 | 1.6 | 5.9 |
| | Exceed 1018 and | | | | |
| | Exceed 3512 | | | | |
| CE 2 | ELITE 5400G | 0.916 | 8.5 | 1.0 | 8.4 |
| CE 3 | ELITE 5500G | 0.914 | 11.2 | 1.5 | 7.3 |
| EX 3 | 08C16R04 | 0.912 | 11.5 | 1.6 | 7.4 |

| | | Unsaturation Unit/1,000,000 C. | | | | |
|---|---|---|---|---|---|---|
| | | vinylene | trisubstituted | vinyl | vinylidene | Total |
| Ex. 1 | 08C16R05 | 6 | 2 | 47 | 7 | 62 |
| Ex. 2 | 09C05R07 VI | 5 | 1 | 59 | 6 | 71 |
| CE 1 | 50/50 blend of | 21 | 46 | 54 | 24 | 145 |
| | Exceed 1018 and | | | | | |
| | Exceed 3512 | | | | | |
| CE 2 | ELITE 5400G | 52 | 51 | 171 | 40 | 314 |
| CE 3 | ELITE 5500 | 41 | 32 | 149 | 30 | 252 |
| Ex. 3 | 08C16R04 | 9 | 2 | 55 | 12 | 78 |
| | | Comonomer | | | | CDC |
| | | dist. | | | HalfWidth/ | (Comonomer |
| | ID | Index | Stdev, C. | HalfWidth, C. | Stdev | Dist. Constant) |
| Ex. 1 | 08C16R05 | 0.873 | 12.301 | 16.823 | 1.368 | 63.8 |
| Ex. 2 | 09C05R07 VI | 0.838 | 6.250 | 3.721 | 0.595 | 140.9 |
| CE 1 | 50/50 Blend of | 0.662 | 10.508 | 25.270 | 2.405 | 27.5 |
| | Exceed 1018 and | | | | | |
| | Exceed 3512 | | | | | |
| CE 2 | ELITE 5400G | 0.515 | 18.448 | 36.739 | 1.991 | 25.9 |
| CE 3 | ELITE 5500 | 0.246 | 27.884 | 42.670 | 1.530 | 16.1 |
| Ex. 3 | 08C16R04 | 0.802 | 11.003 | 5.788 | 0.526 | 152.4 |

CE 1 = 50/50 Blend of Exceed 1018, an ethylene/hexene copolymer having I₂ of 1 g/10 minutes and density of 0.918 g/cm³
and Exceed 3512, an ethylene/hexene copolymer having I₂ of 3.5 g/10 minutes and density of 0.912 g/cm³
CE 2 = ELITE 5400G, an ethylene/octene copolymer having I₂ of 1 g/10 minutes and density of 0.916 g/cm³.
CE 3 = ELITE 5500, an ethylene/octene copolymer having I₂ of 1.5 g/10 minutes and density of 0.914 g/cm³.

| | | DSC Sample | | | |
|---|---|---|---|---|---|
| | | Cool Curve Data | | Heat Curve Data | |
| | | | DeltaH | | DeltaH |
| | | | cryst | | melt |
| | | Tc (C.) | (J/g) | Tm (C.) | (J/g) |
| CE 2 | ELITE 5400 | 105.1 | 141.6 | 123.63 | 143 |
| CE 3 | ELITE 5500 | 106.55 | 137.5 | 124 | 137.4 |
| Ex. 3 | 08C16R04 | 93.97 | 130.4 | 108.33 | 131.7 |
| Ex. 1 | 08C16R05 | 95.21 | 130.7 | 110.82 | 132.2 |
| Ex. 2 | 09C05R07V1 | 112.97 | 179.6 | 123.79 | 178.4 |
| | 50% EXCEED 1018 | | | | |
| CE 1 | 50% EXCEED 3512 | 103.92 | 126.7 | 117.55 | 129.5 |
| | | | Conventional | | |
| | | | GPC | | |
| | Identification | Mn | Mw | Mz | Mw/Mn |
| EX 1 | 08C16R05 | 32,370 | 86,200 | 170,500 | 2.7 |
| EX 2 | 09C05R07v1 | 14,630 | 103,100 | 282,600 | 7.0 |
| | 50/50 BLEND OF | | | | |
| CE 1 | EXCEED 1018 AND | 36,780 | 95,950 | 174,500 | 2.6 |
| | EXCEED 3512 | | | | |
| CE 2 | ELITE 5400G RESIN | 24,600 | 101,900 | 238,200 | 4.1 |
| CE 3 | ELITE 5500G RESIN | 28,800 | 105,100 | 374,900 | 3.6 |
| EX 3 | 08C16R04 | 33,750 | 84,080 | 159,600 | 2.5 |

| | | Shear Rate (1/sec) @190 C. | | | | | | | | | | | |
|---|---|---|---|---|---|---|---|---|---|---|---|---|---|
| | | G′ | | | | G″ | | | | Eta* | | | |
| | | (Pa) | | | | (Pa) | | | | (Pa-s) | | | |
| | | 0.1 | 1 | 10 | 100 | 0.1 | 1 | 10 | 100 | 0.1 | 1 | 10 | 100 |
| EX 1 | 08C16R05 | 66 | 1221 | 12621 | 85376 | 620 | 4696 | 27476 | 102830 | 6240 | 4852 | 3024 | 1337 |
| EX 2 | 09C05R07VI | 1764 | 7855 | 30375 | 111000 | 2756 | 9716 | 33986 | 87314 | 32724 | 12494 | 4558 | 1412 |
| CE 1 | EXCEED 1018/3212 | 8 | 270 | 8214 | 97443 | 378 | 3670 | 29450 | 128860 | 3781 | 3679 | 3057 | 1616 |
| CE 2 | ELITE 5400 | 199 | 2134 | 18203 | 102500 | 957 | 6275 | 32869 | 104710 | 9775 | 6628 | 3757 | 1465 |
| CE 3 | ELITE 5500 | 34 | 892 | 11631 | 86949 | 529 | 4404 | 27610 | 104400 | 5296 | 4493 | 2996 | 1359 |
| EX 3 | 08C16R04 | 52 | 1054 | 11539 | 84139 | 569 | 4411 | 26910 | 103850 | 5716 | 4535 | 2928 | 1337 |

The following prophetic examples further illustrate the invention.

### Film Fabrication:

All resins are blown into monolayer films produced on a Collin three layers blown film line. The blown film line consists of three groove fed extruders with single flight screws (25:30:25 mm). The length/diameter (L/D) ratio for all screws is 25:1. The blown film line has a 60 mm die with dual lip air ring cooling system, with a screen pack configuration of 20:40:60:80:20 mesh. All films are produced at 1 mil thickness.

### Example A

A monolayer 15 mil thick protective film is made from a blend comprising 80 wt % of example 1 polyethylene, 20 wt % of a maleic anhydride (MAH) modified ethylene/1-octene copolymer (ENGAGE® 8400 polyethylene grafted at a level of about 1 wt % MAH, and having a post-modified MI of about 1.25 g/10 min and a density of about 0.87 g/cc), 1.5 wt % of Lupersol® 101, 0.8 wt % of tri-allyl cyanurate, 0.1 wt % of Chimassorb® 944, 0.2 wt % of Naugard® P, and 0.3 wt % of Cyasorb® UV 531. The melt temperature during film formation is kept below about 120 C to avoid premature crosslinking of the film during extrusion. This film is then used to prepare a solar cell module. The film is laminated at a temperature of about 150 C to a superstrate, e.g., a glass cover sheet, and the front surface of a solar cell, and then to the back surface of the solar cell and a backskin material, e.g., another glass cover sheet or any other substrate. The protective film is then subjected to conditions that will ensure that the film is substantially crosslinked.

### Example B

The procedure of Example A is repeated except that the blend comprised 90 wt % example 1 and 10 wt % of a maleic anhydride (MAH) modified ethylene/1-octene (ENGAGE® 8400 polyethylene grafted at a level of about 1 wt % MAH, and having a post-modified MI of about 1.25 g/10 min and a density of about 0.87 g/cc), and the melt temperature during film formation was kept below about 120° C. to avoid premature crosslinking of the film during extrusion.

### Example C

The procedure of Example A is repeated except that the blend comprised 97 wt % example 3 and 3 wt % of vinyl silane (no maleic anhydride modified ENGAGE® 8400 polyethylene), and the melt temperature during film formation was kept below about 120° C. to avoid premature crosslinking of the film during extrusion.

### Formulations and Processing Procedures:

Step 1: Use ZSK-30 extruder with Adhere Screw to compound resin and additive package with or without Amplify.

Step 2: Dry the material from Step 2 for 4 hours at 100 F maximum (use W&C canister dryers).

Step 3: With material hot from dryer, add melted DiCup+Silane+TAC, tumble blend for 15 min and let soak for 4 hours.

TABLE 1
Formulation

| Sample No. | 1 |
|---|---|
| EXAMPLE 1 | 94.7 |
| 4-Hydroxy-TEMPO | 0.05 |
| Cyasorb UV 531 | 0.3 |
| Chimassorb 944 LD | 0.1 |
| Tinuvin 622 LD | 0.1 |
| Naugard P | 0.2 |
| Additives below added via soaking step | |
| Dicup-R Peroxide | 2 |
| Gamma-methacrylo-propyl-trimethoxysilane | 1.75 |
| (Dow Corning Z-6030) | |
| Sartomer SR-507 Tri-Allyl Cyanurate (TAC) | 0.8 |
| Total | 100 |

### Test Methods and Results:

The adhesion with glass is measured using silane-treated glass. The procedure of glass treatment is adapted it from a procedure in Gelest, Inc. “Silanes and Silicones, Catalog 3000 A”.

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The method for testing the adhesion strength between the polymer and glass is the 180 peel test. This is not an ASTM standard test, but it is used to examine the adhesion with glass for PV modules. The test sample is prepared by placing uncured film on the top of the glass, and then curing the film under pressure in a compression molding machine. The molded sample is held under laboratory conditions for two days before the test. The adhesion strength is measured with an Instron machine. The loading rate is 2 in/min, and the test is run under ambient conditions. The test is stopped after a stable peel region is observed (about 2 inches). The ratio of peel load over film width is reported as the adhesion strength.

Several important mechanical properties of the cured films are evaluated using tensile and dynamic mechanical analysis (DMA) methods. The tensile test is run under ambient conditions with a load rate of 2 in/min The DMA method is conducted from −100 to 120° C.

The optical properties are determined as follows: Percent of light transmittance is measured by UV-vis spectroscopy. It measures the absorbance in the wavelength of 250 nm to 1200 nm The internal haze is measured using ASTM D1003-61.

The results are reported in Table 2. The EVA is a fully formulated film available from Etimex.

TABLE 2
Test Results

| Key Properties | EVA |
|---|---|
| Elongation to break (%) | 411.7 |
| STDV* | 17.5 |
| Tensile strength at 85° C. (psi) | 51.2 |
| STDV* | 8.9 |
| Elongation to break at 85° C. (%) | 77.1 |
| STDV* | 16.3 |
| Adhesion with glass (N/mm) | 7 |
| % of transmittance | >97 |
| STDV* | 0.1 |
| Internal Haze | 2.8 |
| STDV* | 0.4 |

*STDV = Standard Deviation.

The adhesion with glass is measured using silane-treated glass. The procedure of glass treatment is adapted it from a procedure in Gelest, Inc. “Silanes and Silicones, Catalog 3000 A”:

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The optical properties are determined as follows: Percent of light transmittance is measured by UV-vis spectroscopy. It measures the absorbance in the wavelength of 250 nm to 1200 nm The internal haze is measured using ASTM D1003-61.

### Example D

### Polyethylene-Based Encapsulant Film

EXAMPLE 1 (made by The Dow Chemical Company) is used in this example. There is 100 ppm of antioxidant, Irganox 1076, in the resin. Several additives are selected to add functionality or improve the long term stability of the resin. They are UV absorbent Cyasorb UV 531, UV-stabilizer Chimassorb 944 LD, antioxidant Tinuvin 622 LD, vinyltrimethoxysilane (VTMS), and peroxide Luperox-101. The formulation in weight percent is described in Table 3.

TABLE 3
Film Formulation

| Formulation | Weight Percent |
|---|---|
| EXAMPLE 1 | 97.34 |
| Cyasorb UV 531 | 0.3 |
| Chimassorb 944 LD | 0.1 |
| Tinuvin 622 LD | 0.1 |
| Irganox-168 | 0.08 |
| Silane (Dow Corning Z-6300) | 2 |
| Luperox-101 | 0.08 |
| Total | 100 |

### Sample Preparation

Example 1 pellets are dried at 40° C. for overnight in a dryer. The pellets and the additives are dry mixed and placed in a drum and tumbled for 30 minutes. Then the silane and peroxide are poured into the drum and tumbled for another 15 minutes. The well-mixed materials are fed to a film extruder for film casting.

Film is cast on a film line (single screw extruder, 24-inch width sheet die) and the processing conditions are summarized in Table 4.

TABLE 4
Process Conditions

| | | | Extruder Die | | | | | | |
|---|---|---|---|---|---|---|---|---|---|
| Sam- | | | Head | | | | | | |
| ple | | | P | Zone | Zone | Zone | Adapter | Adapter | Die |
| # | RPM | Amp | (psi) | 1 (F) | 2 (F) | 3 (F) | (F) | (C) | (C) |
| 1 | 25 | 22 | 2,940 | 300 | 325 | 350 | 350 | 182 | 140 |

An 18-19 mil thick film is saved at 5.3 feet per minute (ft/min) The film sample is sealed in an aluminum bag to avoid UV-irradiation and moisture.

Test Methods and Results

1. Optical Property:

The light transmittance of the film is examined by UV-visible spectrometer (Perkin Elmer UV-Vis 950 with scanning double monochromator and integrating sphere accessory). Samples used for this analysis have a thickness of 15 mils.

2. Adhesion to Glass:

The method used for the adhesion test is a 180° peel test. This is not an ASTM standard test, but has been used to examine the adhesion with glass for photovoltaic module and auto laminate glass applications. The test sample is prepared by placing the film on the top of glass under pressure in a compression molding machine. The desired adhesion width is 1.0 inch. The frame used to hold the sample is 5 inches by 5 inches. A Teflon™ sheet is placed between the glass and the material to separate the glass and polymer for the purpose of test setup. The conditions for the glass/film sample preparation are:
(1) 160° C. for 3 minutes at 80 pounds per square inch (psi) (2000 lbs)
(2) 160° C. for 30 minutes at 320 psi (8000 lbs)
(3) Cool to room temperature at 320 psi (8000 lbs)
(4) Remove the sample from the chase and allow 48 hours for the material to condition at room temperature before the adhesion test.

The adhesion strength is measured with a materials testing system (Instron 5581). The loading rate is 2 inches/minutes and the tests are run at ambient conditions (24° C. and 50% RH). A stable peel region is needed (about 2 inches) to evaluate the adhesion to glass. The ratio of peel load in the stable peel region over the film width is reported as the adhesion strength.

The effect of temperature and moisture on adhesion strength is examined using samples aged in hot water (80° C.) for one week. These samples are molded on glass, then immersed in hot water for one week. These samples are then dried under laboratory conditions for two days before the adhesion test. In comparison, the adhesion strength of the same commercial EVA film as described above is also evaluated under the same conditions. The adhesion strength of the experimental film and the commercial sample are shown in Table 5.

TABLE 5
Tests Results of Adhesion to Glass

| | Conditions for | | Adhesion |
|---|---|---|---|
| Sample | Molding on | Aging | Strength |
| Information | Glass | Condition | (N/mm) |
| Commercial Film | 160° C., one hr | none | 10 |
| (cured) | | | |
| Commercial Film | 160° C., one hr | 80° C. in water | 1 |
| (cured) | | for one week | |

*The sample did not delaminate, but instead began to destroy the film itself.

3. Water Vapor Transmission Rate (WVTR):

The water vapor transmission rate is measured using a permeation analysis instrument (Mocon Permatran W Model 101 K). All WVTR units are in grams per square meter per day (g/(m²-day) measured at 38° C. and 50° C. and 100% RH, an average of two specimens. The commercial EVA film as described above is also tested to compare the moisture barrier properties. The inventive film and the commercial film thickness are 15 mils, and both films are cured at 160° C. for 30 minutes. The results of WVTR testing are reported in Table 6.

TABLE 6
Summary of WVTR Test Results

| | | | | | Permeation | Permeation |
|---|---|---|---|---|---|---|
| | | WVTR | WVTR | | at 38 C. | at 50 C. |
| | Spec- | at 38 C. | at 50 C. | Thick | (g-mil)/ | (g-mil)/ |
| Film | imen | g/(m²-day) | g/(m²-day) | (mil) mil | (m²-day) | (m²-day) |
| Com- | A | 44.52 | 98.74 | 16.80 | 737 | 1660 |
| mercial | | | | | | |
| Film | | | | | | |
| | B | 44.54 | 99.14 | 16.60 | 749 | 1641 |
| | avg. | 44.53 | 98.94 | 16.70 | 743 | 1650 |

### Example E

Two set of samples are prepared to demonstrate that UV absorption can be shifted by using different UV-stabilizers. Example 1 is used and Table 8 reports the formulations with different UV-stabilizers (all amounts are in weight percent). The samples are made using a mixer at a temperature of 190° C. for 5 minutes. Thin films with a thickness of 16 mils are made using a compressing molding machine. The molding conditions are 10 minutes at 160° C., and then cooling to 24° C. in 30 minutes. The UV spectrum is measured using a UV/Vis spectrometer such as a Lambda 950. The results show that different types (and/or combinations) of UV-stabilizers can allow the absorption of UV radiation at a wavelength below 360 nm

TABLE 7
Example 1 with Different UV-Stabilizers

| | Example | Absorber | Cyasorb | Cyasorb | Chimassorb | Chimassorb | Tinuvin |
|---|---|---|---|---|---|---|---|
| Sample | 1 | UV-531 | UV2908 | UV3529 | UV-119 | 944-LD | 622-LD |
| 1 | 100 | | | | | | |
| 2 | 99.7 | 0.3 | | | | | |
| 3 | 99.7 | | 0.3 | | | | |
| 4 | 99.7 | | | 0.3 | | | |
| 5 | 99.7 | | | | 0.3 | | |
| 6 | 99.5 | | | | | 0.25 | 0.25 |
| 7 | 99.85 | 0.15 | | | | | |

Another set of samples are prepared to examine UV-stability. Again, a polyolefin elastomer, Example 1 is selected for this study. Table 8 reports the formulations designed for encapsulant polymers for photovoltaic modules with different UV-stabilizers, silane and peroxide, and antioxidant. These formulations are designed to lower the UV absorbance and at the same time maintain and improved the long term UV-stability.

TABLE 8
Example 1 with Different UV-Stabilizers, Silanes, Peroxides and Antioxidants

| | Engage | Absorber | Cyasorb | Cyasorb | Univil | Doverphos | Hostavin | Chimassorb | Chimassorb | Tinuvin | Western | Irgafos |
|---|---|---|---|---|---|---|---|---|---|---|---|---|
| Samples | 8100 | UV 531 | UV 2908 | UV 3529 | 4050 | S-9228 | N30 | UV 119 | 944 LD | 622 LD | 399 | 166 |
| C 1 | 99.8 | | | | | | | | | | 0.2 | |
| C 2 | 99.3 | 0.3 | | | | | | | 0.1 | 0.1 | 0.2 | |
| C 3 | 99.5 | 0.3 | | | | | | | 0.1 | 0.1 | | |
| 1 | 99.5 | | 0.5 | | | | | | | | | |
| 2 | 99.5 | | | 0.5 | | | | | | | | |
| 3 | 99.5 | | | | | | | 0.5 | | | | |
| 4 | 99.5 | | | | | | | | 0.5 | | | |
| 5 | 99.7 | | | 0.3 | | | | | | 0.5 | | |
| 6 | 99.3 | | | 0.7 | | | | | | | | |
| 7 | 99.5 | | | | 0.5 | | | | | | | |
| 8 | 99.5 | | | | | | 0.5 | | | | | |
| 9 | 99.4 | 0.3 | | | | 0.1 | | | 0.1 | 0.1 | | |
| 10 | 99.3 | 0.3 | | | | | | | 0.1 | 0.1 | | 0.2 |
| 11 | 99.3 | | | 0.5 | | | | | | | | 0.2 |

Although the invention has been described in considerable detail through the preceding description and examples, this detail is for the purpose of illustration and is not to be construed as a limitation on the scope of the invention as it is described in the appended claims. All United States patents, published patent applications and allowed patent applications identified above are incorporated herein by reference.

What is claimed is:

1. An electronic device module comprising:
A. at least one electronic device, and
B. a polymeric material in intimate contact with at least one surface of the electronic device, the polymeric material comprising (1) an ethylene-based polymer composition characterized by a Comonomer Distribution Constant greater than about 45, more preferably greater than 50, most preferably greater than 95, and as high as 400, preferably as high as 200, wherein the composition has less than 120 total unsaturation unit/1,000,000C, preferably the ethylene-based polymer compositions comprise up to about 3 long chain branches/1000 carbons, more preferably from about 0.01 to about 3 long chain branches/1000 carbons; the ethylene-based polymer composition can have a ZSVR of at least 2; the ethylene-based polymer compositions can be further characterized by comprising less than 20 vinylidene unsaturation unit/1,000,000C; the ethylene-based polymer compositions can have a bimodal molecular weight distribution (MWD) or a multi-modal MWD; the ethylene-based polymer compositions can have a comonomer distribution profile comprising a mono or bimodal distribution from 35° C. to 120° C., excluding purge; the ethylene-based polymer compositions can comprise a weight average molecular weight (Mw) from about 17,000 to about 220,000, (2) optionally, a vinyl silane in an amount of at least about 0.1 wt % based on the weight of the copolymer, (3) optionally, a free radical initiator in an amount of at least about 0.05 wt % based on the weight of the copolymer, and (4) optionally, a co-agent in an amount of at least about 0.05 wt % based on the weight of the copolymer.

2. The module of claim 1 in which the electronic device is a solar cell.

3. The module of claim 1 in which the free radical initiator is present.

4. The module of claim 3 in which the coagent is present.

5. The module of claim 4 in which the free radical initiator is a peroxide.

6. The module of claim 1 in which the polymeric material is in the form of a monolayer film in intimate contact with at least one face surface of the electronic device.

7. The module of claim 1 in which the polymeric material further comprises a scorch inhibitor in an amount from about 0.01 to about 1.7 wt %.

8. The module of claim 1 further comprising at least one glass cover sheet.

9. The module of claim 3 in which the free radical initiator is a photoinitiator.

10. The module of claim 1 which the polymeric material further comprises a polyolefin polymer grafted with an unsaturated organic compound containing at least one ethylenic unsaturation and at least one carbonyl group.

11. The module of claim 10 in which the unsaturated organic compound is maleic anhydride.

12. The module of claim 1 in which the vinyl silane is present.

13. The module of claim 12 in which the vinyl silane is at least one of vinyl tri-ethoxy silane and vinyl tri-methoxy silane.

14. The module of claim 13 in which the co-agent is present.

15. The module of claim 13 in which the polyolefin copolymer is crosslinked such that that the copolymer contains less than about 85 percent xylene soluble extractables as measured by ASTM 2765-95.

16. The module of claim 13 in which the polymeric material is in the form of a monolayer film in intimate contact with at least one face surface of the electronic device.

17. The module of claim 13 in which the polymeric material further comprises a scorch inhibitor in an amount from about 0.01 to about 1.7 wt %.

18. The module of claim 13 further comprising at least one glass cover sheet.

19. The module of claim 13 in which the polymeric material further comprises a polyolefin polymer grafted with an unsaturated organic compound containing at least one ethylenic unsaturation and at least one carbonyl group.

20. The module of claim 19 in which the unsaturated organic compound is maleic anhydride.
